(19) United States
(12) Patent Application Publication
(10) Pub. No.: US 2025/0192077 A1
(43) Pub. Date: Jun. 12, 2025

(54) HIGH-ASPECT-RATIO VERTICAL INTERCONNECTS FOR HIGH-FREQUENCY APPLICATIONS

(71) Applicant: CIENA CORPORATION, Hanover, MD (US)

(72) Inventors: Joël Boyer, Ottawa (CA); Arkadiusz Lutkiewicz, Ottawa (CA); François Pellerin, Ottawa (CA); Raphaël Beaupré-Laflamme, Quebec (CA); Gregory Brookes, Quebec (CA)

(73) Assignee: CIENA CORPORATION, Hanover, MD (US)

(21) Appl. No.: 18/679,787

(22) Filed: May 31, 2024

Related U.S. Application Data
(60) Provisional application No. 63/607,820, filed on Dec. 8, 2023.

(51) Int. Cl. H01L 23/66; H01L 21/02; H01L 23/00; H01L 23/498; H01L 25/065

(52) U.S. Cl. CPC H01L 23/66; H01L 21/02098; H01L 23/49838; H01L 24/08; H01L 24/48; H01L 25/0652; H01L 2223/6611; H01L 2223/6616; H01L 2224/08145; H01L 2224/08225; H01L 2224/48138; H01L 2224/48157; H01L 2924/01029; H01L 2924/1421; H01L 2924/3011

(57) ABSTRACT

Aspects of the subject disclosure may include, for example, an Integrated Circuit (IC) assembly. The assembly includes a first die including a first stack of insulating layers having a first overall thickness. The first die further includes a first through-device via configured to provide a first conductive path therethrough. The IC assembly further includes a second die affixed to the first die in a stacked arrangement, the second die including a second stack of insulating layers having a second overall thickness. The second die further includes a second through-device via configured to provide a second conductive path extending therethrough. The second through-device via is electrically coupled to the first through-device via to obtain a through-assembly via configured to provide a through-assembly conductive path extending from the upper surface of the first die to the lower surface of the second die. Other embodiments are disclosed.

### CROSS-REFERENCE TO RELATED APPLICATIONS

The present application claims the benefit of priority to U.S. Provisional Application No. 63/607,820 filed on Dec. 8, 2023, which is hereby incorporated herein by reference in its entirety.

### FIELD OF THE DISCLOSURE

The subject disclosure relates to high-aspect-ratio vertical interconnects for high-frequency applications.

### BACKGROUND

A process referred to as wire bonding supports a transfer of electrical signals and/or power between different components within a semiconductor device. This process is commonly used in the field of chip fabrication, particularly in semiconductor packaging and integrated circuit (IC) fabrication. For example, an extremely thin conductive wire may be electrically bonded at one end to a conductive pad on a semiconductor device, e.g., an IC or chip. An opposite end of the wire may be bonded to another device, such as an electrical lead of a semiconductor package, allowing for signal and/or power transfer to/from the semiconductor device.

### BRIEF DESCRIPTION OF THE DRAWINGS

Reference will now be made to the accompanying drawings, which are not necessarily drawn to scale, and wherein:

FIG. 1 is a block diagram illustrating prior art integrated circuit (IC) assembly.

FIG. 2 is a block diagram illustrating an example, non-limiting embodiment of an IC assembly in accordance with various aspects described herein.

FIG. 3 is a block diagram illustrating an example, non-limiting embodiment of another IC assembly in accordance with various aspects described herein.

FIG. 4 is a block diagram illustrating an example, non-limiting embodiment of an IC riser assembly in accordance with various aspects described herein.

FIG. 5A is a block diagram illustrating a side elevation view of an example, non-limiting embodiment of an IC assembly including a riser assembly in accordance with various aspects described herein.

FIG. 5B is a block diagram illustrating a planar view of the example, non-limiting embodiment of an IC assembly illustrated in FIG. 5A.

FIG. 6A is a block diagram illustrating a side elevation view of an example, non-limiting embodiment of a passive IC riser assembly in accordance with various aspects described herein.

FIG. 6B is a block diagram illustrating, in more detail, a through-device via portion of the example, non-limiting embodiment of the passive IC riser assembly illustrated in FIG. 6A.

FIGS. 7A through 7I are block diagram illustrating an exemplary, non-limiting embodiment of a fabrication of an integrated circuit riser assembly in accordance with various aspects described herein.

FIG. 8A depicts an illustrative embodiment of a micro-via assembly fabrication process in accordance with various aspects described herein.

FIG. 8B depicts an illustrative embodiment of a micro-via device process in accordance with various aspects described herein.

FIG. 9 depicts an illustrative embodiment of a wafer process in accordance with various aspects described herein.

FIG. 10A is a block diagram illustrating a side elevation view of a vertically stacked circuit assembly including an example, non-limiting embodiment of a passive riser device in accordance with various aspects described herein.

FIG. 10B is a block diagram illustrating a side elevation view of a vertically stacked circuit assembly including another example, non-limiting embodiment of a passive riser assembly in accordance with various aspects described herein.

FIG. 11 is a graph illustrating RF performance representative of the example, non-limiting embodiments of the passive riser assemblies illustrated in FIGS. 10A and 10B in accordance with various aspects described herein.

FIG. 12A is a cross-sectional view of an example, non-limiting embodiment of a portion of a passive riser assembly in accordance with various aspects described herein.

FIG. 12B is a perspective view of a prior art, hollow rectangular waveguide.

FIG. 13 is a graph illustrating RF waveguide cutoff frequencies representative of a signal channel of the example, non-limiting embodiments of the passive riser assemblies illustrated in FIGS. 10B and 12A in accordance with various aspects described herein.

### DETAILED DESCRIPTION

The subject disclosure describes, among other things, illustrative embodiments for generating a passive IC assembly having an overlapping arrangement of two or more passive, multi-layer IC devices that include through-device, micro vias. These micro vias, when coupled together to form a through-assembly, micro via, extend a length of the micro via, allowing it to traverse an entire height or thickness of the passive IC assembly. The overlapping IC devices of the passive IC assembly permit a height of the through-assembly, micro via to exceed heights than would otherwise be attainable or practical using a single multi-layer IC device. The passive IC assembly may be used together with and/or in place of other traditional IC interconnection and/or packaging techniques, e.g., wire bonds, to facilitate higher-frequency operation than might otherwise be attainable using wire bonds alone, particularly in view of 3D IC applications.

One or more aspects of the subject disclosure include an integrated circuit (IC) assembly. The IC assembly includes a first IC die that includes a first group of stacked insulating layers having a first thickness extending between upper and lower surfaces of the first IC die. The first IC die further includes a first through-device via configured to provide a first conductive path extending between the upper and lower surfaces of the first IC die. The IC assembly further includes a second IC die affixed to the first IC die in a stacked arrangement, wherein the upper surface of the second IC die is coupled to the lower surface of the first IC die. The second IC die includes a second group of stacked insulating layers having a second thickness extending between upper and lower surfaces of the second IC die. The second IC die further includes a second through-device via configured to provide a second conductive path extending between the upper and lower surfaces of the second IC die. The second through-device via is electrically coupled to the first through-device via to obtain a through-assembly via configured to provide a through-assembly conductive path extending from the upper surface of the first IC die to the lower surface of the second IC die. Other embodiments are described in the subject disclosure.

One or more aspects of the subject disclosure include a process that includes determining a first integrated circuit (IC) die thickness and a second IC die thickness according to a target height value and providing a first, passive IC die. The first, passive IC die includes a first stacked plurality of layers of insulating material extending between an upper first IC die surface and a lower first IC die surface and wherein the first, passive IC die further comprises a first through-die via extending between the upper first IC die surface and the lower first IC die surface separated by the first IC die thickness. The process also includes providing a second, passive IC die that includes a second stacked plurality of layers of insulating material extending between an upper second IC device surface and a lower second IC device surface. The second, passive IC die further includes a second through-die via extending between the upper second IC device surface and the lower second IC device surfaces separated by the second IC die thickness. The lower first IC die surface is fastened to the upper second IC die surface to obtain a multi-die assembly, and the first through-die via is interconnected to the second through-die via to obtain a through-assembly via. The through-assembly via is configured to provide a conductive path extending between the upper first IC die surface and the lower second IC die surface.

One or more aspects of the subject disclosure include a micro-via assembly fabrication process, which includes fabricating a first IC wafer having a first array of first, passive IC circuit. According to the process, a first, passive IC circuit of the first array of first, passive IC circuits includes a first stacked grouping of layers of insulating material and a first through-device micro via extending across a first thickness of the first, passive IC circuit. The first, passive IC circuit is then separated from the first IC wafer to obtain a first, passive IC die. According to the process, a second IC wafer is fabricated to include a second array of second, passive IC circuits. A second, passive IC circuit of the second array of second, passive IC circuits includes a second stacked grouping of layers of insulating material and a second through-device micro via extending across a second thickness of the second, passive IC circuit. A first surface of the first, passive IC die is fastened to a second surface of the second, passive IC circuit to obtain a multi-device assembly. The fastening ensures an electrical alignment between the first through-device micro via and the second through-device micro via. The first through-device micro via is interconnected to the second through-device micro via to obtain a through-assembly micro via configured to provide a conductive path extending across the multi-device assembly. The multi-device assembly is separated from the second IC wafer to obtain a separated multi-device assembly.

Recent trends in miniaturization and improved performance of microsystems have introduced hybrid integration of integrated circuits and micro electromechanical system (MEMS) technology. Hybrid integration may include three-dimensional (3D) integrated system-in-package (3D-SiP) solutions to merge different functionalities into one device and/or to achieve more compact integration. These types of 3D systems may utilize vertical stacking of electronic devices and/or circuits. Without limitation, vertically stacked circuit assemblies may include one or more stacked configurations, such as chip-on-chip, e.g., a flip-chip configuration, chip-on-wafer, wafer-on-wafer, chip on printed circuit board (PCB), chip on SLP (substrate-like PCB), chip on flexible circuit and/or any combination thereof. Vertical electrical interconnections or vias connect different layers of vertically stacked, 3D integrated electronic devices.

A through device via, e.g., a through-silicon via (TSV) is a vertical interconnect that passes through a device, such as a silicon wafer or die. Unlike common vias that connect metal layers on a substrate, TSV passes through the whole substrate or die, e.g., to achieve through-device connections, such as chip-to-chip, chip-to-wafer and/or wafer-to-wafer circuit interconnections. TSVs may be utilized in 3D interconnect technology to replace conventional wire bonding approach, so that multiple electronic devices, e.g., ICs, may be interconnected and packaged together in a 3D stack to integrate the logic, memory and analog devices formed therein with an operating architecture similar to System-on-Chip (SoC). Since the connecting lines for this interconnection approach are set between chips, it may have shorter inner connecting paths that help to increase data transmission speed, reduce the amount of noise and improve overall performance of the device without compromising the high-density requirement, as well as overcoming the obstacles that the SoC technology currently faces in the aspects of process and package.

Typical dimensions of chip and/or wafer-level TSVs include a range of 5-150 μm in diameter, and 20-200 μm in length. The utilization of vias enables an efficient interconnection technique, which leads to a more compact chip design and packaging as compared to conventional wire bonding techniques. Managing such interconnections may take into consideration any combination of design constraints, such as signal wavelengths, voltages, currents and/or power limits, available on-device areas, e.g., to accommodate signal leads and/or bonding pads, numbers, types and/or locations of other electrical interconnections, which may include pitch values indicating spacing among adjacent interconnections, impedance values, e.g., characteristic impedance of signal traces and/or transmission line structures, and so forth. TSV or HDBU core vias, e.g., plated-through holes (PTH) place practical limits on the riser size and thickness for high frequency applications. Longer vias are larger in diameter due to via aspect ratio limits resulting in larger riser size and degraded transmission line. For added RF performance and ease of via fabrication, a “thin core” or “coreless” substrate can be used.

Although the disclosed techniques refer to stacked vertical interconnects suitable for high-frequency operation, e.g., RF risers, other benefits include increasing a total riser stack height, while maintaining high frequency performance. Accordingly, it may be appreciated that although the various examples refer to IC chip applications, the disclosed techniques may be applied more generally applicable in any electronic design requiring high frequency stack height matching. It is worth noting here that, although substantially straight or collinear vertical vias may offer certain advantages in one or more of space savings, performance, e.g., loss and/or impedance, ease of fabrication, and the like, that the processes, devices and systems disclosed herein may incorporate other via configurations including offset vias, blind vias, and combinations thereof.

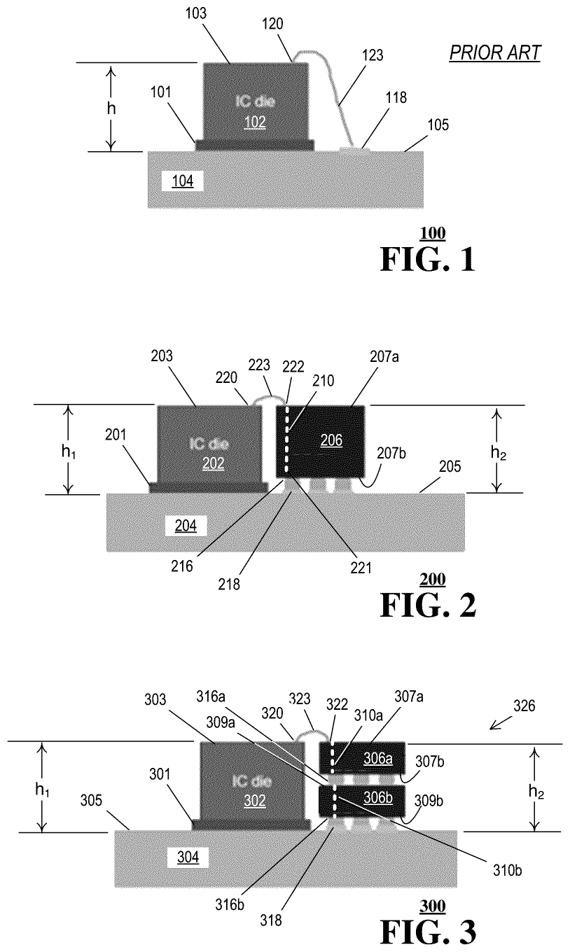

FIG. 1 is a block diagram illustrating prior art integrated circuit (IC) assembly 100. The IC assembly 100 includes an IC die 102 or chip mounted to a substrate 104. A bonding material 101, such as a glue, an epoxy and/or a solder, may be applied between at least a portion of the IC die 102 and a substrate surface 105 to facilitate securing the IC die 102 to the substrate 104. More generally, a physical bonding process may include an application of one or more of a mechanical connection, such as a fastener, an adhesive, heat, pressure, a weld, chemical bonds, e.g., solder. A die surface 103 of the IC die 102, e.g., a top surface, is positioned at a height h above the substrate surface 105. In this instance, the die surface 103 is displaced from the substrate surface 105 according to thicknesses of the IC die 102 and the bonding material 101. The IC die 102 includes an IC bonding contact 120 at the die surface 103, while the substrate 104 includes an electrical conductor, a lead or a bonding pad 118 at the substrate surface 105. The IC assembly 100 further includes a wire bond 123 in electrical communication between the IC bonding contact 120 and the bonding pad 118. The wire bond 123 may include a length of wire extending between the IC bonding contact 120 and the bonding pad 118. The wire bond 123 may be used for an exchange of signals and/or power between the IC die 102 and another electrical circuit external to the IC die 102.

It is recognized that wire bonds are inductive in nature, which may limit operations at high frequencies, e.g., frequencies at which a length of the wire bond 123 represents a significant portion of a signal wavelength λ_{signal}. Without limitation, a significant portion of the signal wavelength may be determined as a fractional portion of the signal wavelength λ_{signal}, e.g., a 1%, 10% or 25% portion of λ_{signal}. Thus, reducing the length of the wire bond 123 may permit operation at higher frequencies. To this end, the IC die 102 may be positioned as close as possible with respect to a horizontal separation along the substrate surface 105 to minimize horizontal separation, i.e., adjacent to any interconnecting device, such as the example bonding pad 118. It is further recognized, however, that in many instances there may be a vertical height difference offset Δh between the IC bonding contact 120 and the bonding pad 118. In this example, the height offset represents a difference between the height of the IC die 102 and the bonding material 101, such that Δh≈h. It is envisioned that relatively substantial vertical height differences will be encountered in high-density IC applications due to the vertical integration of devices. Thus, even if the IC die 102 is proximate to an interconnecting device, e.g., the bonding pad 118, a minimum wire length of the interconnecting wire bond 123 will be limited due to the substantial height difference Δh.

FIG. 2 is a block diagram illustrating an example, non-limiting embodiment of an IC assembly 200 in accordance with various aspects described herein. The IC assembly 200 includes an IC die 202 mounted to a substrate surface 205 of a substrate 204. A die surface 203 of the IC die 202, e.g., a top surface, is positioned at a height h₁ above the substrate surface 205. In this instance, the die surface 203 is displaced from the substrate surface 205 according to a thickness of the IC die 202 and a bonding material 201. The IC die 202 includes an IC bonding contact 220 at the die surface 203, while the substrate 204 includes an electrical conductor, a lead or a bonding pad 218 at the substrate surface 205. The IC assembly 200 also includes a vertical interconnection device, sometimes referred to as a riser device or an RF riser device 206 for high-frequency applications, positioned proximate to an adjacent edge of the IC die 202. The RF riser device 206 may be placed next to the IC die 202 to adjust, e.g., to elevate, an RF signal path to an active layer of the IC die 202, e.g., proximate to the die surface 203, in an impedance-controlled manner. It is recognized that wire bond lengths should be as short as possible for high-frequency or RF applications. The resulting adjustment to the signal path facilitates a reduction in wire length of a traditional wire bond, while also facilitating an overall improved RF performance in comparison to the traditional wire bond.

According to the illustrative example, the RF riser device 206 includes an electrically conducting, through-device via 210 extending between its upper and lower surfaces 207a, 207b. One end of the through-device via 210 is in electrical communication with an upper riser bonding contact 222 positioned at the upper surface 207a, while an opposite end of the through-device via 210 is in communication with a lower riser bonding contact 221 positioned at the lower surface 207b. The IC assembly 200 further includes a wire bond 223 in electrical communication between the IC bonding contact 220 and the upper riser bonding contact 222 of the RF riser device 206. The lower riser bonding contact 221 may be in electrical communication with the bonding pad 218 of the substrate 204 via an interstitial conductive element, such as a solder bump 216. It is envisioned that the RF riser device 206 may be mounted to the substrate 204 using any suitable IC fabrication technique, such as surface mounting, e.g., via solder paste and/or solder bumps.

Accordingly, to the illustrative example, the RF riser device 206 in combination with the wire bond 223 provides an electrically conductive path from the IC die 202 to the substrate 204. The wire bond 223 has a sufficient length to span a horizontal separation distance between the IC die 202 and the RF riser device 206, as well as any vertical offset Δh between the die surface 203 and the upper surface 207a of the RF riser device 206. It is envisioned that the RF riser device 206 may be produced having a predetermined height that may be determined at least in part to a threshold vertical offset value Δh_{T}. Beneficially, a length of the wire bond 223 may be substantially less than would otherwise be necessary without the RF riser device 206. The RF riser device 206 facilitates a reduction of electrical path lengths for an exchange of signals and/or power between the IC die 202 and the substrate 204. In at least some embodiments, the reduction of electrical path lengths of the wire bond 223. A shorter wire generally permits conveyance of electrical signals at higher frequencies than would otherwise be permissible with a longer, traditional wire bond 123 (FIG. 1).

The upper surface 207a of the RF riser device 206 is positioned at an overall, installed height h₂ above the substrate surface 205. A height offset Δh between the IC die 202 and the RF riser device 206 may be calculated as a difference between the height values, i.e., Δh≈h₁−h₂. It is understood that the height of the IC die 202 may be determined according to a particular construction of the IC die 202. Without limitation, the IC die 202 may include an individual die and/or multiple die joined together in a stacked and/or otherwise overlapping arrangement that may include one or more interposers. For applications in which an overall, installed height h₁ of the IC die 202 is fixed, it may be appreciated that the difference between the height values Δh may be determined at least in part by the overall, installed height h₂ of the RF riser device 206, e.g., when mounted on the substrate 204. In at least some embodiments, the overall, installed height h₂ of the RF riser device 206 mounted to the substrate 204 may be determined to minimize the height difference Δh and/or otherwise match the height h₁ of the IC die 202.

In at least some embodiments, the through-device via 210 provides a preferential path through the RF riser device 206 that offers reduced adverse effects, e.g., capacitive, resistive, and inductive parasitic effects, in comparison to the traditional wire bond 123 (FIG. 1). A preferential path of the through-device via 210 may include one or more of a predetermined path, a predetermined impedance characteristic, a predetermined loss characteristic. It is envisioned that a preferential path of the through-device via 210 may include a transmission line structure, such as parallel lines, a coaxial line, and the like. For example, a coaxial via may include a signal via in proximity to one or more adjacent ground vias that in at least some embodiments, may encircle at least a portion of the signal via. In at least some embodiments, the preferential path may include other predetermined characteristics, such as any combination of one or more of a characteristic impedance, an electrical conductivity, a reactance, e.g., an inductance and/or a capacitance, a permittivity, a permeability, a voltage breakdown threshold, a current carrying capacity, and the like. It is envisioned that at least some of these characteristics may be determined at least in part by a diameter, length and/or aspect ratio of the through-device via 210, a type(s) of conductive material(s) used along the electrically conductive path of the through-device via 210, a type(s) of insulating material(s) included within the RF riser device 206, and particularly proximate to the through-device via 210, as well as any other constructs and/or devices of the RF riser device 206, such as bonding contacts, leads, circuit routing, antennas, transmission lines, and the like. For at least these reasons, any adverse effect of a circuit length of the through-device via 210 through the RF riser device 206 can be distinguished from a corresponding length of the traditional wire bond 123 (FIG. 1). It is understood that the through-device via 210 may be configured to facilitate high-frequency operation, e.g., being sized and/or otherwise configured for high-frequency operation. For example, the through-device via 210 may provide less inductance than a bonding wire and/or operate at least in part as a transmission line.

According to the illustrative embodiment, no restrictions are placed upon the height h₁ of the example IC die 202. Namely, the IC die 202 may include overlapping and/or stacked configurations of similar and/or dissimilar layers, such as any combination of one or more IC dice, wafers, PCB devices, structural supports, substrates, chip carriers, packaging layers and the like, having an overall, installed height h₁ determined at least in part by a sum of the heights of the individual contributing layers. A height difference Δh between the overall, installed height h₁ of the IC die 202 and overall height h₂ of the RF riser device 206 may be controlled according to a predetermined height difference, e.g., less than a height difference threshold Δh_{T}. In at least some embodiments, the overall height h₂ of the RF riser device 206 may be substantial, e.g., being equivalent to and/or approximately close to the unrestricted height value h₁ of the IC die 202. Consequently, construction of a relatively thick RF riser device 206 may pose challenges.

In at least some embodiments, the RF riser device 206 is a relatively small device, e.g., having dimensions comparable to the IC die 202, the bonding pad 218 and/or other device and/or circuits as may be included within the IC assembly 200. Accordingly, size and/or spacing or pitch of the upper and lower riser bonding contacts 222, 221 as well as size and/or spacing or pitch of the IC bonding contact 220 may be extremely small, e.g., on the order of a few to tens of micrometers. In at least some embodiments, the through-device vias 210, e.g., of the same RF riser device 206, may have similar size and/or spacing restrictions, e.g., having diameters and/or spacing or pitch on the order of a few to tens of microns.

FIG. 3 is a block diagram illustrating an example, non-limiting embodiment of another IC assembly 300 in accordance with various aspects described herein. The IC assembly 300 includes an IC die 302 mounted to a substrate surface 305 of a substrate 304. A die surface 303 of the IC die 302, e.g., an upper or top surface, is positioned at a height h₁ above the substrate surface 305. In this instance, the die surface 303 is displaced from the substrate surface 305 according to a thickness of the IC die 302 and a bonding material 301. The IC die 302 includes an IC bonding contact 320 at the die surface 303, while the substrate 304 includes an electrical conductor, a lead or a bonding pad 318 at the substrate surface 305. The IC assembly 300 also includes a vertical interconnection assembly, sometimes referred to as a riser assembly or an RF riser assembly 326 for high-frequency applications, positioned proximate to an adjacent edge of the IC die 302. The RF riser assembly 326 may be placed next to the IC die 302 to adjust, e.g., to elevate, an RF signal path to an active layer of the IC die 302, e.g., proximate to the die surface 303, in an impedance-controlled manner. The resulting adjustment to the signal path facilitates a reduction in wire length of a traditional wire bond, while also facilitating an overall improved RF performance in comparison to the traditional wire bond. The example IC assembly 300 includes a wire bond 323 between adjacent surfaces of the IC die 302 and the RF riser assembly 326. A stack height of the RF riser assembly 326 may facilitate a reduction in a length of the wire bond 323.

According to the illustrative example, the RF riser assembly 326 includes a first riser device 306a and a second riser device 306b configured in a stacked arrangement. The first riser device 306a includes a first through via 310a extending between its upper and lower surfaces 307a, 307b. Likewise, the second riser device 306b includes a second through via 310b extending between its upper and lower surfaces 309a, 309b. One end of the first through via 310a is in electrical communication with an upper riser bonding contact 322 positioned at the upper surface 307a, while an opposite end of the first through via 310a is in communication with a first conductive contact 316a positioned between the lower surface 307b of the first riser 306a and the upper surface 309a of the second riser device 306b. An upper end of the second through via 310b is in electrical communication with first conductive contact 316a, while lower end of the second through via 310b is in communication with a second conductive contact 316b positioned between the lower surface 309b of the second riser device 306b and the bonding pad 318 of the substrate 304. It is envisioned that the second riser device 306b may be mounted to the substrate 304 using any suitable IC fabrication technique for securing devices, such as surface mounting, e.g., via solder paste and/or solder bumps. Alternatively, or in addition, the first riser device 306a may be mounted to the second riser device 306b using any suitable IC fabrication technique for securing devices, such as surface mounting, e.g., via solder paste and/or solder bumps.

The first and second through vias 310a, 310b together with the first conductive contact 316a provide an electrically conductive path between the upper surface 307a of the first riser device 306a and the lower surface 309b of the second riser device 306b. The electrically interconnected through vias 310a, 310b provide a preferential path through the RF riser assembly 326 that offers reduced adverse effects, e.g., capacitive, resistive, and inductive parasitic effects, in comparison to the traditional wire bond 123 (FIG. 1). Accordingly, the RF riser assembly 326 in combination with the wire bond 323 provides an electrically conductive path from the IC die 302 to the substrate 304. Adverse effects that might otherwise be experienced due to a long wire bond may be avoided by allowing a relatively short wire bond 323.

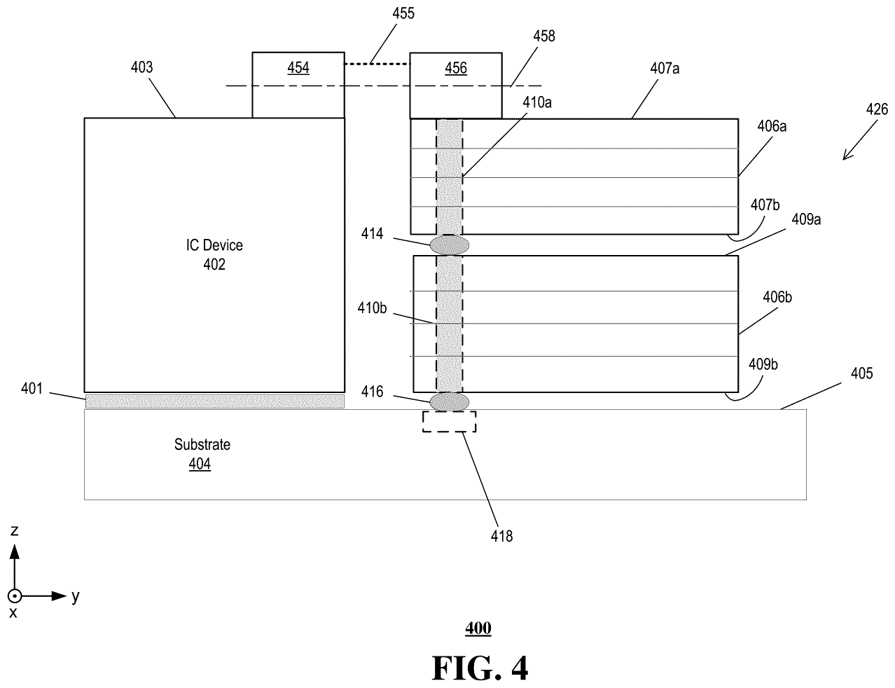

FIG. 4 is a block diagram illustrating an example, non-limiting embodiment of an IC riser assembly 400 in accordance with various aspects described herein. The IC riser assembly 400 includes an IC device 402 mounted to a substrate surface 405 of a substrate 404. A die surface 403 of the IC device 402, e.g., a top surface, is positioned at a height above the substrate surface 405. In this instance, the die surface 403 is displaced from the substrate surface 405 according to a thickness of the IC device 402 and a bonding material 401. A first terminal device 454 is positioned at the die surface 403, while the substrate 404 includes an electrical conductor, a lead or a bonding pad 418 at the substrate surface 405. The IC riser assembly 400 also includes a vertical interconnection assembly, sometimes referred to as a riser assembly or an RF riser assembly 426 for high-frequency applications, positioned proximate to an adjacent edge of the IC device 402. The RF riser assembly 426 may be placed next to the IC device 402 and configured to include a second terminal device 456. The RF riser assembly may be further configured to adjust an alignment between the first and second terminal devices 454, 456. In this example, the first and second terminal devices 454, 456 are aligned along a common axis 458 to facilitate establishment of a link 455 therebetween. It is envisioned that other alignments may be achieved as may be beneficial for establishing a link 455, e.g., the first and second terminal devices 454, 456 not aligned along a common axis 458, but otherwise configured to facilitate establishment of the link.

In some embodiments, the first and second terminal devices 454, 456 include the IC bonding contacts 220, 320 and/or the upper riser bonding contacts 222, 322 (FIGS. 2-3) configured to facilitate wireless communication therebetween, the link 455 including a wire bond 223, 323. Alternatively, or in addition, the first and second terminal devices 454, 456 include electrical connectors configured to facilitate electrical communication therebetween via the link 455 including an electrical circuit. The electrical connectors may be adapted for mechanical coupling, capacitive coupling, inductive coupling, ohmic coupling, or any combination thereof to provide the electrical circuit of the link 455. In at least some embodiments, the first and second terminal devices 454, 456 include wireless devices configured to facilitate wireless communication therebetween via the link 455. Wireless communications may include, without limitation, RF, optical, infrared, ultrasonic, or any combination thereof. Wireless devices may include, without limitation, antennas, piezoelectric devices, waveguides, including optical fibers, optical devices, including infrared devices, such as laser diodes, light emitting diodes, photodiodes. In at least some embodiments, at least one of the first and second terminal devices 454, 456 includes and/or is part of a micro-electromechanical system (MEMS).

A stack height of the RF riser assembly 426 may facilitate a proximate relationship of the first and second terminal devices 454, 456 to facilitate establishment of the link 455 therebetween, while also providing a suitable path through the RF riser assembly 426 that offers reduced adverse effects, e.g., capacitive, resistive, and inductive parasitic effects, in comparison to the traditional wire bond 123 (FIG. 1).

According to the illustrative example, the RF riser assembly 426 includes a first riser device 406a and a second riser device 406b configured in a stacked arrangement. The first riser device 406a includes a first through via 410a extending between its upper and lower surfaces 407a, 407b. Likewise, the second riser device 406b includes a second through via 410b extending between its upper and lower surfaces 409a, 409b. One end of the first through via 410a is in electrical communication with the second terminal device 456 positioned at the upper surface 407a, while an opposite end of the first through via 410a is in communication with a first conductive contact 414 positioned between the lower surface 407b of the first riser device 406a and the upper surface 409a of the second riser device 406b. An upper end of the second through via 410b is in electrical communication with first conductive contact 414, while lower end of the second through via 410b is in communication with a second conductive contact 416 positioned between the lower surface 409b of the second riser device 406b and the bonding pad 418 of the substrate 404. It is envisioned that the second riser device 406b may be mounted to the substrate 404 using any suitable IC fabrication technique for securing devices, such as surface mounting, e.g., via solder paste and/or solder bumps. Alternatively, or in addition, the first riser device 406a may be mounted to the second riser device 406b using any suitable IC fabrication technique for securing devices, such as surface mounting, e.g., via solder paste and/or solder bumps.

The first and second through vias 410a, 410b together with the first conductive contact 414 provide an electrically conductive path between the upper surface 407a of the first riser device 406a and the lower surface 409b of the second riser device 406b. Accordingly, the RF riser assembly 426 in combination with the first and second terminal devices 454, 456 facilitate establishment of the link 455 between the IC device 402 and the bonding pad 418, while also providing an electrically conductive path from the second terminal device 456 to the substrate 404. Adverse effects that might otherwise be experienced due to a long wire bond may be avoided by utilizing a combination of the first and second through vias 410a, 410b.

According to the illustrative example, a predetermined alignment configured to facilitate establishment of the link 455 may require a predetermined or target offset value Δh_{Target} between the die surface 403 and the upper surface 407a of the RF riser assembly 426. Given a height h₁ of the IC device 402, a target overall, installed height h₂of the RF riser assembly 426 installed on the substrate 404 may be determined according to the target offset value, as:

$${h}_{2} = Δ {h}_{T a rget} - {h}_{1} \qquad ( Eq . 1 )$$

If target offset value Δh_{Target} is chosen to be zero, then h₂=h₁.

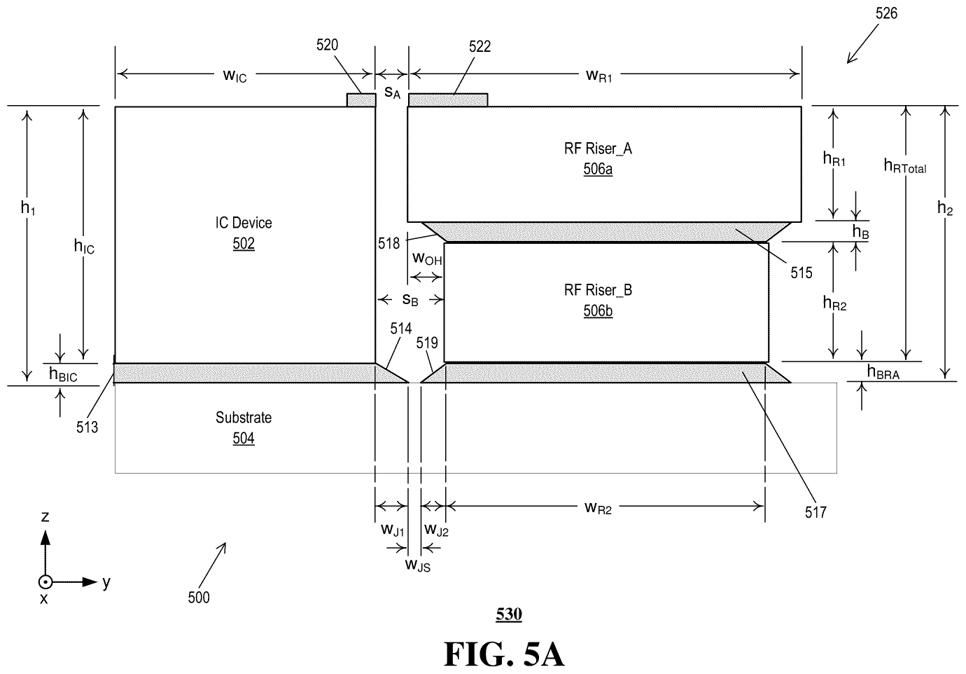

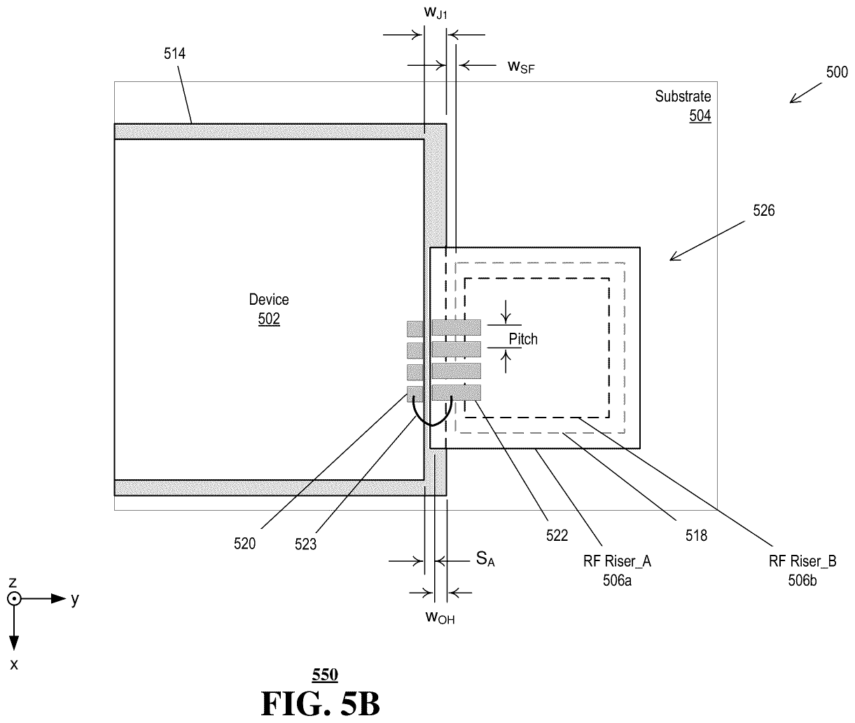

FIG. 5A is a block diagram illustrating a side elevation view 530 of the example, non-limiting embodiment of an IC assembly 500 including a riser assembly in accordance with various aspects described herein. The IC assembly 500 includes an IC device 502 mounted to a substrate 504 that is positioned in or otherwise parallel to the x-y plane. The IC device 502 has an IC device thickness or height h_{IC} extending along a z-direction, away from the substrate 504. In this instance, a top surface of the IC device 502 displaced from a surface of the substrate 504 by a first height h₁, determined according to a sum of the IC device height h_{IC} and an IC-device bonding material thickness or height h_{BIC} of the IC-device bonding material 513 used to secure the IC device 502 to the substrate 504.

The IC assembly 500 further includes a riser assembly 526 that includes one or more electrically conducting, vertical structures, e.g., vias. At least some of the vias extend through the riser assembly 526, sometimes referred to as through-vias, providing a structured electrical circuit path from an upper surface to a lower surface of the riser assembly 526. The riser assembly 526 has an overall riser assembly thickness or height h_{R}. According to the illustrative embodiment, the riser assembly 526 includes two riser devices: an upper riser device 506a, having a respective z-directed thickness or height h_{R1}; and a lower riser device 506b having a respective z-directed thickness or height h_{R2}. The overall riser assembly height h_{R} of the riser assembly 526 includes a sum of the individual heights h_{R1}+h_{R2} of the upper and lower riser devices 506a, 506b, as well as a first assembly bonding material thickness or height hp of a riser-device bonding material 515 as may be used to secure the upper and lower riser devices 506a, 506b together. In this instance, a top surface of the riser assembly 526 is displaced from the substrate 504 by an overall height h₂, determined according to a combination of the overall riser assembly height h_{R} of the riser assembly 526 and a riser-assembly bonding material thickness or height h_{BRA} of a riser-assembly bonding material 517 used to secure the riser assembly 526 to the substrate 504.

Two electrical or bonding terminals are provided for reference, as may be employed in a wire bond configuration. Namely, the IC device 502 includes a first bonding pad 520 positioned along an upper surface of the IC device 502, whereas the riser assembly 526 includes a second bonding pad 522 positioned along an upper surface of the riser assembly 526, i.e., along an upper surface of the upper riser device 506a. The first height h₁ may be established by thicknesses of the IC device 502, the IC-device bonding material 513, and perhaps any other intervening device or devices. The IC device 502 may be determined according to a function of the IC assembly 500 and, in at least some embodiments, without regard to its height h_{IC}. In at least some embodiments, the IC device 502 itself may include an assembly of other devices, such as a stacked and/or otherwise overlapping structure including any combination of two or more of IC chips, wafers, interposers, flip-chips, and/or PCB devices. Likewise, the thickness of the IC-device bonding material 513 may be determined according to a device fabrication process and, in at least some embodiments, without regard to its thickness h_{BIC}.

In at least some embodiments, the riser assembly 526 may be constructed as an independent device, e.g., including two or more riser devices 506a, 506b, generally 506, fixedly coupled together, such that the riser assembly 526 may be provided as a component device that may be mounted to another device, such as the example substrate 504, e.g., according to a surface mounting process. A minimum thickness or height h_{Rmin} of a stack of the upper and lower riser devices 506a, 506b without the bonding material may be determined according to a sum of the riser device thicknesses, i.e., h_{Rmin}=h_{R1}+h_{R2}. An overall thickness or height h_{RTotal} of the riser assembly 526 adds to minimum thickness or height h_{Rmin}, a thickness of the bonding material h_{B} used to secure the upper and lower riser devices 506a, 506b. Accordingly, the overall thickness or height of the riser assembly 526 may be determined according to the following relationship:

$${h}_{RTotal} = {h}_{Rmin} + {h}_{B} = ( {h}_{R 1} + {h}_{R 2} ) + {h}_{B} \qquad ( Eq . 2 )$$

It is understood that the techniques disclosed herein may apply to arrangements with two or more riser devices that may be arranged with or without overhangs, which overhangs may be symmetric or asymmetric. For example, equation 2 may be adjusted to consider situations in which the riser assembly 526 includes more than two riser devices 506. By way of example, a riser assembly 526 having a total of N stacked riser devices 506 may include N-1 bonding layers applied during a fabrication process of the riser assembly 526, to secure the N riser devices 506 together, e.g., as a single device. It is further envisioned that an assembled, N-layer riser assembly 526 may be attached, interconnected, secured and/or otherwise bonded to another device, e.g., the substrate 504, with another bonding layer.

Once a first height h₁ or displacement of the first bonding pad 520 of the IC device 502 has been determined and/or otherwise established, it is understood that that an overall, installed height h₂ or displacement of the second bonding pad 522 may be determined so as to establish a relative height difference Δh between the values h₁ and h₂. The relative height difference may be used as a design parameter, e.g., establishing an approximating a design or target value Δh_{Target}, which may be represented as Δh_{Target}≈|h₂−h₁|. Alternatively, or in addition, the overall, installed height h₂ or displacement of the second bonding pad 522 may be determined to establish a relative height difference Δh falling within a target range, e.g., below a threshold value Δh_{Threshold}, which may be represented as Δh_{Threshold}≥|h₂−h₁|. Given the values h₁ and Δh_{Target} or Δh_{Threshold}, as the case may be, the value and/or range h₂ may be solved according to the foregoing relationships. Having determined the necessary value and/or range h₂, a design process may be undertaken to determine a configuration of the riser assembly 526.

According to the illustrative example, the riser assembly 526 includes two riser devices, an upper riser device 506a and a lower riser device 506b, generally 506. It is understood that in at least some embodiments, the riser assembly 526 may include more than two riser devices, e.g., three, four or even more riser devices 506. In at least some embodiments, the riser devices 506 of the riser assembly 526 may have substantially the same thickness or height, i.e., h_{R1}≈h_{R2}. Alternatively, or in addition, two or more riser devices 506 within the same riser assembly 526 may have different thicknesses or heights, i.e., h_{R1}≠h_{R2}. An overall thickness or height hR_{Total} of the riser assembly 526 generally includes a combination or sum of the thicknesses or heights h_{R} of the individual riser devices 506 and the thicknesses or heights h_{B} of any riser-device bonding material 515 that may be included between adjacent riser devices 506.

In at least some embodiments, one or more individual riser devices 506 may be prefabricated according to one, two, and/or perhaps some other generally limited or small number of standard thicknesses or heights h_{R1}, h_{R2}, h_{R3}, . . . . It is envisioned that a riser assembly may be formed with a stacked arrangement of two or more such prefabricated individual riser devices 506. A required number of prefabricated individual riser devices 506 and/or types, e.g., thicknesses or heights, may be determined according to the overall riser assembly height h_{RTotal}, which in turn, may be determined according to an overall, installed height h₂, as presented above.

In at least some embodiments, a thickness and or height h_{B} of one or more layers of the riser-device bonding material 515 and/or the riser-assembly bonding material 517 may be selectable and/or adjustable, e.g., during assembly of the riser assembly 526. Such selectable thicknesses and or heights h_{Bn} of an n^{th} bonding layer may be achieved in at least some embodiments according to a thickness of a solder ball, a solder bump and/or solder paste as may be applied as one or more of the riser-device and/or riser-assembly bonding materials 515, 517 according to surface mounting processes during fabrication of the riser assembly 526 and/or the IC assembly 500.

A thickness or height h_{RTotal} of the riser assembly 526 may be determined as a sum of the heights of n individual device layers h_{R} and n-1 bonding layers h_{Bn}, as set forth below:

$${h}_{RTotal} = {\sum }_{n = 1}^{N} {h}_{R n} + {\sum }_{n = 1}^{N - 1} {h}_{B n} \qquad ( Eq . 3 )$$

To the extent the heights of the riser devices 506 are substantially equivalent and the heights of the bonding layers are substantially equivalent, the foregoing expression may be represented as set forth below:

$${h}_{RTotal} = N {h}_{R} + ( N - 1 ) {h}_{B} \qquad ( Eq . 4 )$$

It is understood that in at least some embodiments, a stacked arrangement determined in this manner may be determined and/or otherwise optimized to minimize a required number of prefabricated individual riser devices 506 and/or a number of types of individual riser devices 506. In at least some embodiments, optimization may take into consideration minimizing a number N of required riser devices 506. The riser devices 506 may be prepared according to a common thickness or height, and/or to some number of predetermined heights. In at least some embodiments, the riser-device bonding material 515 may be deployed in a manner that provides at least some variability. For example, a thickness of a solder paste may be variable between some minimum and maximum values, h_{Bmin}, h_{Bmax} to ensure a reliable solder bond. In some embodiments, thicknesses of the bonding layers may be restricted to a common, uniform value, e.g., falling within the variable range. Alternatively, or in addition, thicknesses of the bonding layers may have at least some variability between different riser devices 506 of the same riser assembly 526. An optimization process may take into account any of the foregoing possibilities and/or restrictions in order to minimize a quantity, such as a total number of riser devices 506 and/or a thickness and/or amount of bonding material.

It is worth noting that in at least some embodiments, at least a portion of one or more of the bonding materials 513, 515, 517 used to attach, interconnect, secure and/or otherwise bond structures together, may extend beyond one or more edges of a bonded device along a joined edge. According to the illustrative example, an excess portion of the IC-device bonding material 513 extends beyond at least one edge of the IC device 502 when bonded to the substrate 504 to form an exposed or protruding IC-device joint edge 514. At least a portion of the protruding IC-device joint edge 514, viewed in side elevation, may form an angular, e.g., trapezoidal, shape as may be found in a chamfer joint. Alternatively, or in addition, at least a portion of the protruding IC-device joint edge 514, viewed in side elevation, may form a relatively smooth, e.g., arcuate or curved, shape as may be found in a fillet joint. Likewise, an excess portion of the riser-device bonding material 515 may extend beyond at least one edge of the lower riser device 506b when bonded to the upper riser device 506a, resulting in an exposed or protruding riser-device joint edge 518. Similarly, an excess portion of the riser-assembly bonding material 517 may extend beyond at least one edge of the riser assembly 526 when bonded to the substrate 504, the resulting in an exposed or protruding riser-assembly joint edge 519.

It is understood that in at least some scenarios, exposed or protruding portion of one or more of the IC-device joint edge 514, the protruding riser-device joined edge 518 and/or the protruding riser-assembly joint edge 519 may be a consequence of the type of bonding material, the amount of bonding material, and/or the bonding process. Thus, in at least some embodiments, exposure and/or protrusion of the joined edges beyond a perimeter of a joined device may be unavoidable. According to the illustrative example, the protruding IC-device joint edge 514 extends to a joint-edge width W_{J1} beyond an edge of the IC device 502. It is apparent that the joint-edge width effectively expands a lateral footprint of the assembled IC device 502 when mounted to the substrate 504. Consequently, the joint-edge width W_{J1} effectively limits a minimum spacing or separation between devices, such as a second separation distance S_{B} between adjacent edges of the IC device 502 and the lower riser assembly 506b. This situation may be exacerbated by the protruding riser-assembly joint edge 519, which extends to a joint-edge width W_{J2} beyond an edge of the lower riser device 506b. Accordingly, an achievable second separation distance S_{B} may be represented by the following expression:

$${S}_{B} = {W}_{J 1} + {W}_{J 2} + {W}_{J S} \qquad ( Eq . 5 )$$

This expression includes a joint spacing or separation distance W_{JS} to account for any intended and/or otherwise unavoidable separation between adjacent joint edges. In a limiting scenario, this value may be set to zero.

It is understood that in at least some applications, an intended benefit of the riser assembly 526 is to reduce a wire bond length between the bonding pads 520, 522. In this regard, any limitation to an achievable minimum value of the contact separation distance S_{A}, e.g., S_{Amin}, would be undesirable. In at least some embodiments, the riser assembly 526 may be configured to incorporate an overlapping and/or stacked arrangement of the riser devices 506 that facilitates a reduction of the contact separation distance S_{A} towards the minimum contact separation distance S_{Amin}, than would otherwise be achievable in view of the extended widths W_{J1}, W_{J2} of any exposed and/or protruding joint edges 514, 519. For example, dimensions of a riser device 506 within the riser assembly 526 may differ, e.g., having different widths and/or diameters in a horizontal plane. According to the illustrative example, the upper riser device 506a has an upper-device width W_{R1}, whereas the lower riser device 506b has a lower-device width W_{R2}.

In the example configuration, the upper-device width is greater than the lower-device width, i.e., W_{R1}>W_{R2}. This permits at least one edge of the upper device 506a to overhang an edge of the lower device 506b by an overhang width W_{OH}. Consequently, a first, or contact, separation distance S_{A} is provided between adjacent edges of the IC device 502 and the upper riser device 506a and a second separation distance S_{B} is provided between adjacent edges of the IC device 502 and lower riser device 506b. It is understood that, without limitation, an overhang arrangement may be provided according to a symmetric arrangement and/or an asymmetric arrangement. For example, in a symmetric arrangement, a degree of the overhang width may be determined at least in part by the dimensional differences of the upper and lower devices 506a, 506b as indicated in the following expression:

$${W}_{OH} = ( {W}_{R 1} - {W}_{R 2} ) / 2 \qquad ( Eq . 6 )$$

In view of a positive overhang width W_{OH}, the second separation distance S_{B} would be greater than the contact separation distance S_{A}. Beneficially, the second separation S_{B} may be treated as a design parameter. For example, the second separation distance S_{B} may be selected according to any combination of one or more of a joint-edge width W_{J1} of the exposed or protruding IC-device joint edge 514, a joint-edge width W_{J2} of the exposed or protruding riser-assembly joint edge 519 and/or the joint spacing or separation distance W_{JS}. To the extent that the joint-edge widths W_{J1} and W_{J2} have been established, an assembly base separation distance S_{B} may be determined according to equation 5, in which the separation distance W_{JS} may be a selectable non-negative value:

$${S}_{Bmin} = {W}_{J 1} + {W}_{J 2} \qquad ( Eq . 7 )$$

A minimum assembly base separation distance S_{Bmin} may be determined by setting the separation distance W_{JS} to be approximately zero, as in equation 7.

Beneficially, the positive overhang width W_{OH} allows for a decoupling of the contact separation distance S_{A} and the assembly base separation distance S_{B}. For example, a width W_{R2} and/or alignment of the lower riser device 506b may be determined according to equation 6, independently from a contact separation distance S_{A}, which may be determined at least in part on the overhang width W_{OH}. A greater assembly base separation distance S_{B} would necessitate a greater overhang width W_{OH} to ensure a particular or predetermined contact separation distance S_{A} as may be determined or selected according to a design process.

In having the two riser devices 506a, 506b of slightly different sizes, this arrangement has an additional benefit at the upper riser device 506a, as per the example side elevation view 530. The upper riser device 506a can be brought very close to the IC device 502, which reduces a bond wire length. This is attributable, at least in part, to complimentary underfill space usage at the lower riser device 506b.

Accordingly, a positive overhang width W_{OH} may be determined according to a difference in device widths, e.g., W_{R1}>W_{R2}. Alternatively, or in addition, according to a stacking alignment of the riser devices 506, e.g., by displacing a lower riser device 506b in a direction away from the IC device 502 to sufficiently introduce a particular or predetermined assembly separation distance S_{B} as may be determined according to a design process. Such alignment variations can produce a desired separation without necessarily imposing restrictions upon the device widths. Accordingly, the lower-device width W_{R2}, may be greater than, less than, or substantially equal to the upper-device width W_{R1}, the separation distance S_{B} being attributable at least in part to the alignment, e.g., offset. It is conceivable that in at least some embodiments the shapes of one or more of the riser devices 506 may be determined to sufficiently introduce a particular or predetermined assembly separation distance S_{B} as may be determined according to a design process. For example, the lower riser device 506b may include a curve and/or a notch and/or some other curvilinear departure from a straight edge that accommodates, at least in part, one or more of the protruding joint edges 514, 519.

FIG. 5B is a block diagram illustrating a planar view 550 of an example, non-limiting embodiment of the IC assembly 500 illustrated in FIG. 5A. The IC device 502 is coupled to the substrate 504 in a position adjacent to the riser assembly 526, which is also coupled to the substrate. The protruding IC-device joint edge 514 is visible, extending beyond a perimeter of the IC device 502 by an IC joint-edge width W_{J1}. The relative positioning of the IC device 502 and the riser assembly 526 places the bonding pads 520, 522 in relatively close proximity, separated by a contact separation distance S_{A}. It is apparent from the planar view 550 that at least an upper riser device 506a overhangs at least a portion of the protruding IC-device joint edge 514 by an overhang width W_{OH}. According to the illustrative example, a wire bond 523 is coupled between the bonding pads 520, 522.

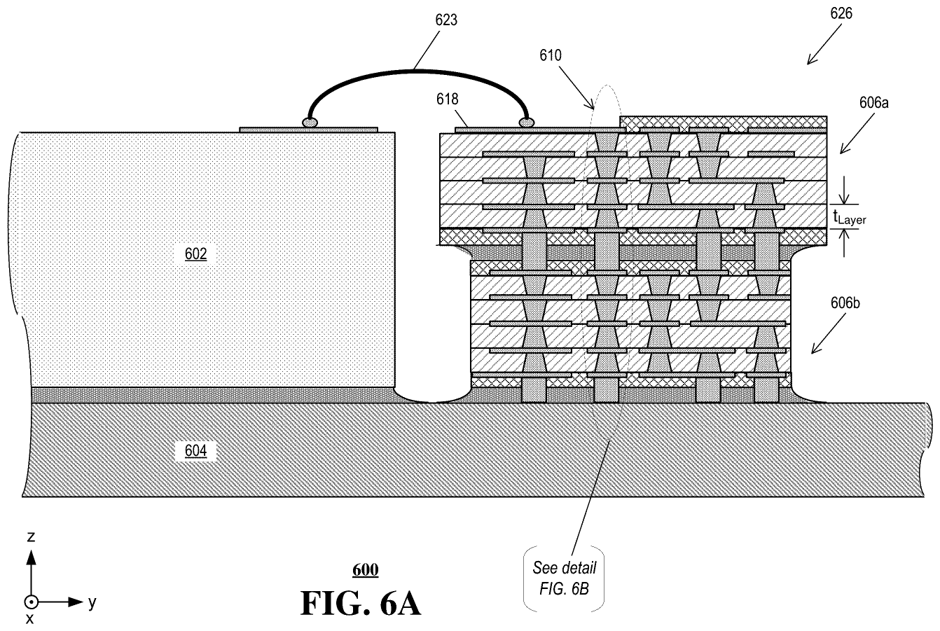

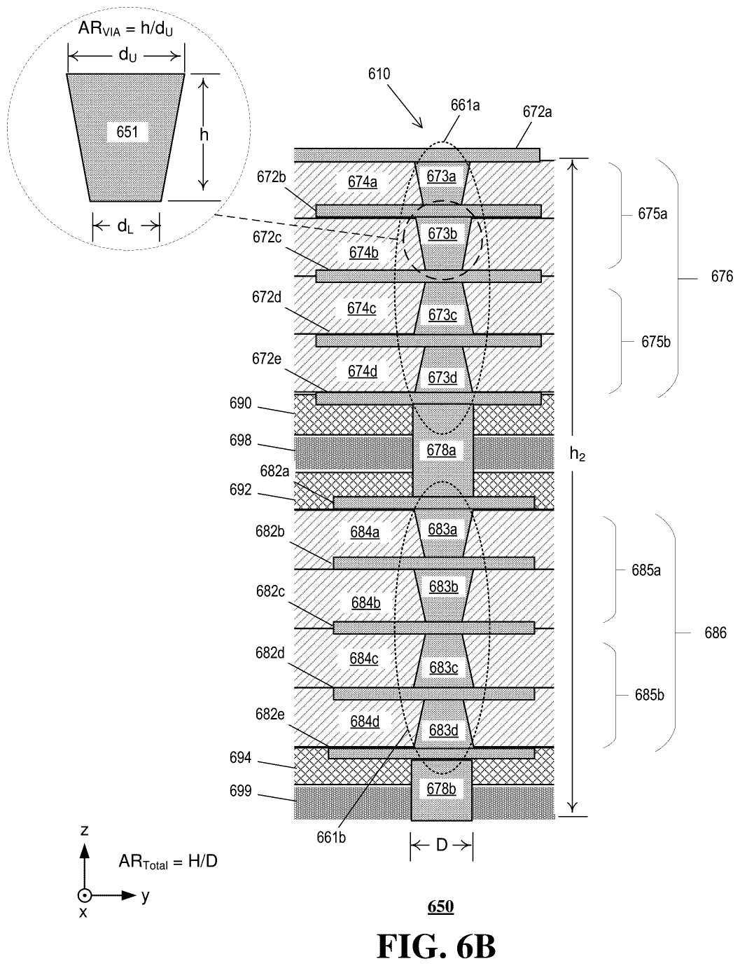

FIG. 6A is a block diagram illustrating a cross-sectional view of an example, non-limiting embodiment of a passive IC riser assembly 600 in accordance with various aspects described herein. The passive IC riser assembly 600 includes a first device 602 attached to a surface of a substrate 604 and a riser assembly 626 also attached to the surface of the substrate and proximate to the first device 602. The substrate 604 provides an underlying supporting layer. In at least some embodiments, the substrate includes a mechanical support, which, in at least some embodiments, may be substantially rigid to ensure a proximate relationship between the first device 602 and the riser assembly 626.

By way of example and without limitation, the substrate 604 may include one or more of a PCB, a supporting die, e.g., a master die, which may include a semiconductor device, a wafer, an interposer, a chip riser assembly, an IC package, and the like. The substrate 604 may include any combination of one or more of an insulator, a semiconductor, a metal, a glass, a ceramic, a polymer, an organic compound, an inorganic compound, and so on. In at least some embodiments, the substrate 604 may include and/or otherwise support one or more of an insulating layer, a metal layer and/or a semiconductor layer. A metal layer, when provided, may include an electrical contact 618, e.g., a circuit element or trace and/or wire.

The first device 602 may include a single IC device or any combination of one or more IC devices, e.g., stacked and/or otherwise arranged according to a vertical integration extending vertically away from the surface of the substrate 604. Alternatively, or in addition, the first device 602 may include one or more of an IC die, a wafer, a PCB, an interposer, an insulator, and the like.

The riser assembly 626 includes a layered, upper riser device 606a having a surface positioned at a height that approximates a height of the first device 602. The riser assembly 626 also includes a layered, lower riser device 606b positioned at a bottom portion of the riser assembly 626. Although two layered, riser devices 606a, 606b, generally 606, are shown, it is understood that one or more additional layered, riser devices may be stacked and/or otherwise positioned in an overlapping arrangement of the riser assembly 626. A number of riser devices may be determined, at least in part, according to an available, e.g., a maximum available height of available individual risers 606 and/or a height of the proximate first device 602.

The riser assembly 626 further includes at least one through-riser-assembly via circuit 610. The through-riser-assembly via circuit 610 provides a substantially vertical, electrically conducting path, sometimes referred to as a through-device via. The through-riser-assembly via circuit 610 extends from a top surface of the layered, upper riser device 606a to a bottom surface of the layered, lower riser device 606b, also traversing any other intervening layered riser devices 606 as may be included in a stacked arrangement of the riser assembly 626. According to the illustrative example, the through-riser-assembly via circuit 610 provides an electrically conducting path between the electrical contact 618 at the substrate 604 and one end of a wire bond 623 coupled at another end to the proximate first device 602.

According to the techniques disclosed herein, the through-riser-assembly via circuit 610 provides a controlled signal path in which one or more of an electrical resistance, capacitance and/or inductance are controlled to facilitate high-frequency and/or low loss signal transmission and/or an efficient transfer of power. For example, the through-riser-assembly via circuit 610 may provide a transmission line having a controlled characteristic impedance. The transmission line may be configured to ensure relatively low signal loss or loss tangent. Alternatively, or in addition, the transmission line may be configured to offer a relatively low insertion loss and/or a relatively low return loss. Other advantages may include, without limitation, signal integrity, e.g., offering an improved signal isolation and/or a reduction of crosstalk.

FIG. 6B is a block diagram illustrating, in more detail, a cross-sectional view 650 of the through-riser-assembly via circuit 610 of the example, non-limiting embodiment of the passive IC riser assembly 600 illustrated in FIG. 6A. The through-riser-assembly via circuit 610 includes a first through-riser-device via circuit 661a, extending through a first multi-layer riser device 676. The multi-layer riser device 676 includes four riser-device layers 674a, 674b, 674c, 674d, generally 674. In at least some embodiments, the riser-device layers 674 are formed from an insulating material, which may be chose, at least in part, according to one or more material properties, such as the material's electrical permittivity and/or magnetic permeability. In at least some embodiments, the riser-device layers 674 may have approximately the same layer thickness. Alternatively, or in addition, at least some of the riser-device layers 674 may have different layer thicknesses. In at least some embodiments, the riser-device layers 674 may be formed from substantially the same insulating material. Alternatively, or in addition, at least some of the riser-device layers 674 may be formed from one or more different insulating materials. In at least some embodiments, the insulating material used in at least some of the riser-device layers 674 may include, without limitation, amorphous materials, e.g., glass, some ceramics, crystalline materials, e.g., silicon, quartz, some ceramics. In at least some embodiments, the insulating material may include one or more organic materials, such as polymers. The organic materials may include amorphous materials, crystalline materials or combinations of both amorphous and crystalline materials.

In at least some embodiments, each riser-device layer 674 includes at least one respective through-layer via 673a, 673b, 673c, 673d, generally 673. The through-layer vias 673 provide electrically conductive paths through their respective riser-device layers 674. In at least some embodiments, through-layer vias 673 of at least some adjacent riser-device layers 674 may be in electrical communication with each other. Alternatively, or in addition, the through-riser-assembly via circuit 610 may include one or more electrically conducting layers, e.g., metal layers, which may provide electrical contacts 672a, 672b, 672c, 672d, generally 672, in electrical communication with one or more of the through-layer vias 673. In at least some embodiments, the electrical contact 672 may include a metal layer in electrical communication between adjacent through-layer vias 673. Alternatively, or in addition, the electrical contact 672 may include a conductive coating and/or fill applied to an aperture formed within the riser-device layer 674, e.g., to obtain an electrically conductive through-layer via 673 as an integral component of the through-riser-assembly via circuit 610. In at least some embodiments, the through-layer vias 673 may be arranged in a colinear manner, e.g., along a common axis. At least some of the electrical contacts 672 may be aligned with the through-layer vias 673, which together provide an electrically conductive path of the first through-riser-device via circuit 661a. Alternatively, or in addition, at least some of the through-layer vias 673 may be arranged in an off-axis configuration. For example, at least some of the electrical contacts 672 may be configured, e.g., extending horizontally within the metal plane, to ensure an electrical coupling of off-axis through-layer vias 673 of the adjacent layers 674. In at least some embodiments, at least some of the electrical contacts 672 may provide a suitable conductive area to accommodate attachment to another device, such as a bonding wire. According to the illustrative example, an upper-most, exposed electrical contact 672a may serve as a bonding contact for attachment of the wire bond 623 (FIG. 6A).

In at least some embodiments, the first multi-layer riser device 676 includes a base device layer 690. The base device layer may be provided as one of the riser-device layers, e.g., having the same material properties of the other riser-device layers 674. Alternatively, or in addition, the base device layer 690 may differ from the other riser-device layers 674. For example, the base device layer 690 may have one or more of a different thickness, a different stiffness, a different chemical bonding property from the other riser-device layers 674.

The example through-riser-assembly via circuit 610 includes a second through-riser-device via circuit 661b, extending through a second multi-layer riser device 686. The second multi-layer riser device 686 also includes four riser-device layers 684a, 684b, 684c, 684d, generally 684, although it is understood that in at least some embodiments, the first and second multi-layer riser devices 676, 686 may differ with respect to their number, material composition and/or circuit configuration of riser-device layers 684. Once again, the riser-device layers 684 may be formed from the same and/or different insulating materials and may have approximately the same and/or different layer thicknesses.

In at least some embodiments, each riser-device layer 684 includes at least one respective through-layer via 683a, 683b, 683c, 683d, generally 683. The through-layer vias 683 provide electrically conductive paths through their respective riser-device layers 684. In at least some embodiments, an electrically conducting layer, e.g., a metal layer, may provide bonding contacts 682a, 682b, 682c, 682d, generally 682, in electrical communication with the through-layer vias 683. In at least some embodiments, the through-layer vias 683 may be arranged in a colinear manner and/or according to an off-axis configuration. The bonding contacts 682 may be configured, e.g., extending horizontally within the metal plane, to ensure an electrical coupling of through-layer vias 683 of adjacent layers.

In at least some embodiments, the second multi-layer riser device 686 includes one or more of a first and second outer device layers 692, 694. The first outer device layer 692 may be positioned along an upper surface of the second multi-layer riser device 686, whereas the second outer device layer 694 may be positioned along a lower surface of the second multi-layer riser device 686. In at least some embodiments, the first and second outer device layers 692, 694 may be provided as riser-device layers 684, e.g., having the same material properties of the other riser-device layers 684. Alternatively, or in addition, at least one of the first and second outer device layers 692, 694 may differ from the other riser-device layers 684. For example, either or both first and second outer device layers 692, 694 may have one or more of a different thickness, a different stiffness, a different chemical bonding property from the other riser-device layers 684.

The riser assembly 626 (FIG. 6A) may include an inter-device bonding layer 698 configured to securely couple the first multi-layer riser device 676 to the second multi-layer riser device 686. Alternatively, or in addition, the riser assembly 626 may include an assembly bonding layer 699 configured to securely couple the second multi-layer riser device 686 to the substrate 604 (FIG. 6A). The bonding layers 698, 699 may include any suitable bonding material and/or bonding process, such as the various bonding processes used in semiconductor device fabrication and/or packaging, including the various examples disclosed herein. It is understood that the bonding layers 698, 699 may be substantially similar and/or substantially different in one or more of composition, e.g., material type, process, e.g., chemical, thermal, and/or configuration, e.g., thickness.

In at least some embodiments, a first electrical coupling 678a extends at least partially through one or more of the base device layer 690 of the first multi-layer riser device 676, the inter-device bonding layer 698 and the first outer device layer 692 of the second multi-layer riser device 686. Alternatively, or in addition, a second electrical coupling 678b extends at least partially through the second outer device layer 694 and the assembly bonding layer 699. The first electrical coupling 678a and/or the second electrical coupling 678b may include one or more of a conductive column, e.g., a via, a solder bump, a solder ball and/or a solder paste as may be applied according to a surface-mounting process as may be used in PCB and/or semiconductor device assemblies.

It is understood that the size or scale of the various devices disclosed herein may be extremely small according to the IC devices and assemblies. This scale includes diameters of any of the example vias, as well as sizes and/or inter-via spacing, e.g., inter-via pitch. Such dimensions may be on the order of tens of microns, to a few microns, trending towards sub-micron dimensions as IC devices become smaller and multi-IC assemblies become more complex. Generally, vias me be formed using a mechanical device, such as a drill, e.g., computer numerical control (CNC) mechanical drilling. As the drill dimeters are reduced, however, the ability to drill relatively deep holes becomes limited, e.g., by drill breakage and/or drift or alignment. Other via forming techniques include laser-drilling, in which a laser beam is applied to a device layer, with energy of the laser beam removing material along a columnar path of the laser, sometimes referred to as laser ablated micro vias. A byproduct of the laser drilling process is a hole or well having sloped sides, e.g., an opening at the top of the well is greater than an opening at the bottom of the well. According to either drilling technique, an aspect AR ratio may be used to characterize an achievable depth or thickness h given a via diameter d, i.e., AR=h/d.

Mechanical drilling may be capable of via diameters of about 0.1 mm, with aspect ratios of less than about 8:1, via diameters of about 0.20 mm, with aspect ratio of less than about 10:1, or via diameters of about 0.25 mm, with aspect ratio of less than about 12:1. Laser ablation drilling may be capable of via diameters of about 0.025 mm to about 0.15 mm, with aspect ratios ranging from about 0.75:1 to about 1:1.

FIG. 6B includes an inset detailing a construction of a via well 651 formed within one of the insulating layers 674b of the first multi-layer riser device 676. The via well 651 is trapezoidal in cross section, having an upper diameter d_{U} that is greater than a lower diameter d_{L}, i.e., d_{U}>d_{L}. The shape of the via well 651 suggests a directionality, namely that in this instance, the via was formed from the top. Accordingly, a drilling laser beam was applied to a top surface of the insulating layer 674b, with energy of the laser removing portions of the insulating material over time. In this manner, the longer the laser beam was applied, the deeper it drilled into the insulating layer 674b. Consequently, continued application of the laser beam to already exposed portions of the insulting layer 674b resulted in an expansion of the well's diameter when viewed from bottom to top.

If a single via had been drilled through all the insulating layers 674 of the first multi-layer riser device 676, the opening of the well, i.e., an opening at a top of the via, would be expected to have a relatively large diameter according to the aspect ratio resulting from the drilling process—the greater the height or depth of drilling, the greater the exposed diameter of the resulting well. According to the disclosed layering process, a first through-riser-device via circuit 661a may be formed incrementally. With this approach, any aspect ratio limitations may apply within each layer, but they would apply independently and not to the overall first through-riser-device via circuit 661a. It is understood that in at least some embodiments, a maximum diameter dₘₐₓ of a first through-riser-device via circuit 661a may be established according to a design process. The maximum diameter may be either an upper diameter or a lower diameter of a drilled well, depending upon a direction of the drilling. Thus, the maximum diameter dₘₐₓ may correspond to an upper diameter d_{U} or a lower diameter d_{L}, as the case may be.

According to an example design process, an overall height h₂ of a riser assembly 626 (FIG. 6A) may be established and/or otherwise determined according to a height h₁ of an IC device to which the riser assembly 626 will be associated for interaction, e.g., via a wire bond 623. Establishment of the overall height h₂ may take into consideration any height offset Δh as may be necessary to attain a desired interaction. Further according to the example design process, a maximum layer thickness t_{Layer_Max}, e.g., according to limitations of a drilling process and/or an aspect ratio attainable by the drilling process. In at least some embodiments according to the example design process, a maximum device height h_{r_max} may be determined based on limitations of a riser device assembly process, e.g., of layering process, such as physical limitations, cost limitations and/or complexity limitations associated with greater number N of layers. Having established a maximum device height h_{r_max}, and an overall height h₂, a number of devices may be determined, e.g., N≈h₂/h_{r_max}, then rounding up to the next highest whole number.

It is envisioned that a height of a riser device hᵣ may be any value up to and including the maximum achievable h_{r_max}. In at least some embodiments, one or more riser devices may be prefabricated at one or more heights, e.g., off-the-shelf values, such as h₁, h₂, in which h₁>h₂. In this instance, a number and/or type of riser devices may be selected to achieve the overall riser assembly height value h₂, e.g., mh₁+nh₂≤(h₂−minimum bonding thicknesses), in which m and n are positive integer values.

It is worth noting here that a first group of the first two riser-device layers 674a, 674b of the first multi-layer riser device 676, include through-layer via 673a, 673b having a first direction, e.g., downward drilling. Similarly, a second group of the next two riser-device layers 674c, 674d of the first multi-layer riser device 676, include through-layer vias 673c, 673d having a second direction, e.g., upward drilling. This configuration may be obtained according to a laminate technology as may be achieved using a build-up processes, e.g., high density build-up (HDBU).

Organic substrates of more than approximately 350 μm, e.g., from about 500 μm to about 1000 μm, cannot use Si or glass substrates and generally require a reinforced core for rigidity, such as a glass fiber reinforced dielectric core. Unfortunately, thick cores generally require mechanically drilled vias of larger drill and pad sizes than laser drilled vias. It is understood that such reinforcements and/or larger vias add to via transition complexity and negatively impacts signal integrity at high frequencies.

A fabrication process, such as an organic process, e.g., HDBU, may be used to generate multi-layer riser devices 676, 686 having 2, 4, 6, 8 layers or potentially more. According to this process, a first dielectric layer may be formed upon a base core device, sometimes referred to as a thin-core process. Laser vias, e.g., using a laser ablation technique may be used to form vias in the first dielectric layer. The drilled holes may then be plated through, and resin filled, followed by a cap metallization plating. The metallization layer may be patterned, e.g., applying a circuitization using a subtractive process, such as chemical etching. The patterning process may result in via contacts at one or both ends of a plated and resin filled via. The process may be repeated a number of times to build up successive layers in a similar manner, resulting in a first stacked layer device. It is envisioned that the vias would be unidirectional as the laser ablation is performed from one direction.

In at least some embodiments, the base core device first stacked layer device may be removed, e.g., by a mechanical process, such as grinding. The resulting coreless first stacked layer device may serve as a base core device for a second multi-layer generation process, sometimes referred to as a coreless process. For example, the resulting coreless first stacked layer device may be inverted, with a second group of layers being formed thereupon as described above. According to this configuration, the vias of the second group of layers would be unidirectional, but in an opposite direction from those of the first stacked layer device.

The first multi-layer riser device 676 provides an example that may have been obtained with this type of fabrication process. The first multi-layer riser device 676 includes a stacked arrangement of a first group of riser-device layers 675a and a second group of riser-device layers 675b. It is apparent that the vias of a first group of first group of riser-device layers 675a are directed downward, while the vias of the second group of riser-device layers 675b are directed upward. Likewise, the second multi-layer riser device 686 includes a stacked arrangement of a first group of riser-device layers 685a and a second group of riser-device layers 685b. It is apparent that the vias of a first group of first group of riser-device layers 685a are directed downward, while the vias of the second group of riser-device layers 685b are directed upward. The process may be completed any number of times to achieve a desired thickness of the multi-layer riser devices 676, 686.

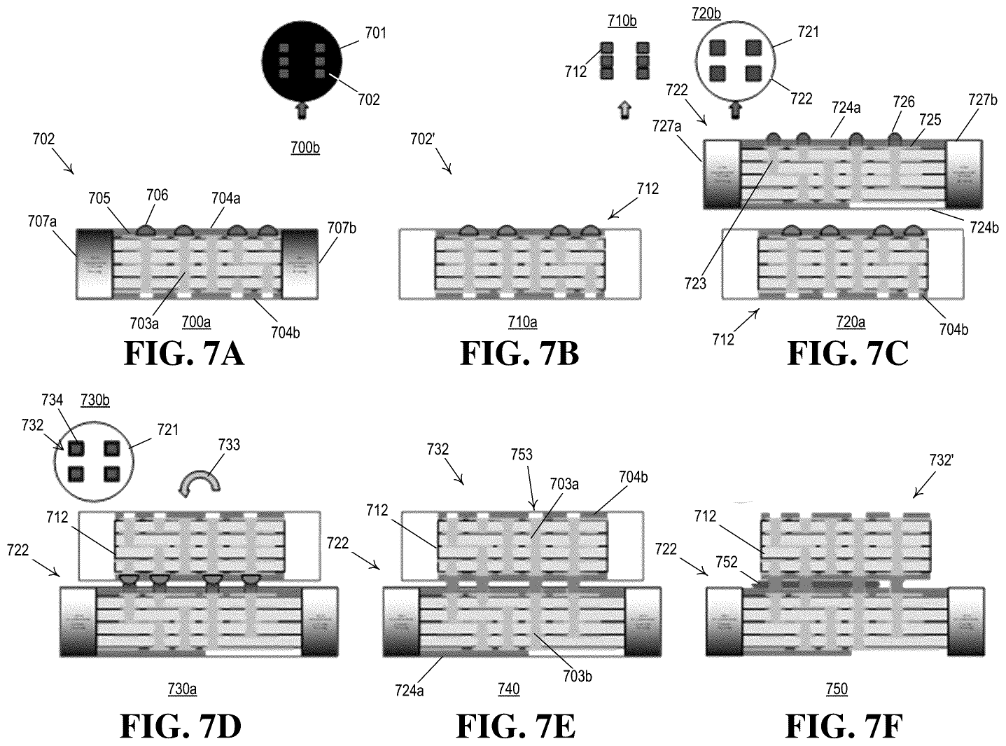

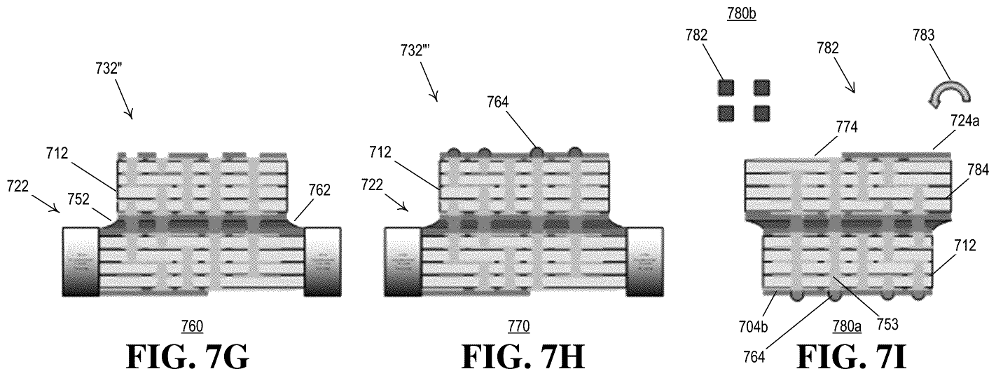

FIGS. 7A-7I are block diagram illustrating an exemplary, non-limiting embodiment of a fabrication of an integrated circuit riser assembly in accordance with various aspects described herein. FIG. 7A is block diagram illustrating a cross-sectional view 700a of a first on-wafer die 702 including an exemplary, non-limiting embodiment of a first riser of integrated circuit riser assembly in accordance with various aspects described herein. In at least some embodiments a first riser device may be fabricated using a wafer process. In this regard, the cross-sectional view 700a illustrates a cross section of the first on-wafer die 702. The first on-wafer die 702 includes a first group of through-device vias, including a first device via 703a, extending from a first exposed wafer surface 704a to a second exposed wafer surface 704b of the first wafer 701. The illustrative cross section includes non-functional wafer regions 707a, 707b, generally 707 as may be present between adjacent first on-wafer die 702. An illustration insert 700b illustrates a planar top view of a first wafer 701, which includes an array of first on-wafer dies 702, at least some of which conform to the illustrative the cross-sectional view 700a. The first exposed wafer surface 704a may include a first group of solder bumps 706, balls or other suitable electrical contacts. The solder bumps of the first group of solder bumps 706 may be isolated from each other by a solder resist material that may be deposited upon the first exposed wafer surface 704a, e.g., according to a surface-mount process.

FIG. 7B is block diagram illustrating a cross-sectional view 710a of separated die 702′ in which the first on-wafer die 702 (FIG. 7A) was liberated from the first wafer 701 according to a first dicing process. It is envisioned that any suitable dicing process may be used, e.g., mechanical sawing or laser cutting. An illustration insert 710b illustrates a planar top view of a wafer-separated, first multi-layer die 712, representing the first on-wafer dice 702 that have been separate from the first wafer 701, i.e., “diced.”

FIG. 7C is block diagram illustrating a cross-sectional view 720a of a second on-wafer die 722 including an exemplary, non-limiting embodiment of a second riser of integrated circuit riser assembly in accordance with various aspects described herein. The second on-wafer die 722 is positioned relative to the wafer-separated, first multi-layer die 712. It is apparent from the illustration that a dimension, e.g., a width, of the second on-wafer die 722 is greater than a width of the wafer-separated, first multi-layer die 712.

In at least some embodiments a second riser device may be fabricated using a wafer process. In this regard, the cross-sectional view 720a of the second on-wafer die 722 illustrates a cross section of the second on-wafer die 722. The second on-wafer die 722 includes a second group of through-device vias 723 extending from an exposed second wafer surface 724a to a second exposed, second underside surface 724b of the second wafer 721. The illustrative cross section includes non-functional wafer regions 727a, 727b, generally 727 as may be present between adjacent second on-wafer die 722. An illustration insert 720b illustrates a planar top view of the second wafer 721, which includes a second array of on-wafer dies 722, at least some of which conform to the illustrative cross-sectional view 720a of the second on-wafer die 722. The exposed second wafer surface 724a may include a second group of solder bumps 726, balls or other suitable electrical contacts. The solder bumps of the second group of solder bumps 726 may be isolated from each other by a solder resist material that may be deposited upon the exposed second wafer surface 724a, e.g., according to a surface-mount process.

FIG. 7D is block diagram illustrating a cross-sectional view 730a of a second on-wafer die 722. The wafer-separated, first multi-layer die 712 has been inverted at 733, aligned and/or otherwise positioned on a surface of the second on-wafer die 722, such that the first group of solder bumps 706 aligns with the second group of solder bumps 726. It is apparent from the illustration that the non-functional wafer regions 727 extend beyond the edges of the aligned wafer-separated, first multi-layer die 712. A drawing insert 730b illustrates a planar view of a wafer assembly 732, in which an exposed annular region 734 of the second on-wafer die 722 is visible. The exposed annular region represents that portion of the second on-wafer die 722 extending beyond an outer edge of the overlapping first multi-layer die 712.

FIG. 7E is block diagram illustrating a cross-sectional view 740a of a portion of the wafer assembly 732. This process reflects that a bonding between the first and second groups of solder bumps 706, 726 has been performed, e.g., according to surface mounting process, such as a solder flow process. The first device via 703a of the wafer-separated, first multi-layer die 712 is bonded to a second device via 703b extending through the second on-wafer die 722. The first and second device vias 703a, 703b, when bonded together, result in a through-assembly via 753, extending from one end at the second exposed wafer surface 704b of the wafer-separated, first multi-layer die 712 to an opposite end at an exposed surface of the second on-wafer die 722.

FIG. 7F is block diagram illustrating a cross-sectional view 750a of a portion of a wafer assembly 732′ after a bonding material 752, e.g., a glue or an epoxy, has been introduced between the wafer-separated, first multi-layer die 712 and the second on-wafer die 722. The bonding process may include an adhesive bonding (also referred to as gluing or glue bonding) as an example of a wafer bonding technique that applies an intermediate layer of material, e.g., a bonding material 752, to connect substrates of different types of materials. Those connections produced can be soluble or insoluble. Adhesives may include commercially available adhesives that may be organic or inorganic and deposited on one or both substrate surfaces. The intermediate layer of bonding material 752 may be applied by spin-on, spray-on, screen-printing, embossing, dispensing or block printing on one or two substrate surfaces.

FIG. 7G is block diagram illustrating a cross-sectional view 760 of a portion of a wafer assembly 732″ after the bonding material 752 has set. In at least some embodiments, a protruding or extended region of the bonding material 762 may extend beyond an edge of the wafer-separated, first multi-layer die 712 and along a joint formed between the wafer-separated, first multi-layer die 712 and the second on-wafer die 722.

FIG. 7H is block diagram illustrating a cross-sectional view 770 of a portion of a wafer assembly 732″′ after solder bumps 764, solder balls and/or solder paste have been formed and/or otherwise applied along an exposed surface of the wafer assembly 732″.

FIG. 7I is block diagram illustrating a cross-sectional view 780a of separated riser assemblies 782 in which the wafer assembly 732″′ (FIG. 7H) was liberated from the wafer assembly 732″′ according to a second dicing process. It is envisioned once again that any suitable dicing process may be used, e.g., mechanical sawing or laser cutting. An illustration insert 780b illustrates a planar top view of a wafer-separated, riser assemblies 782 have been separate from the second wafer 721, i.e., “diced.” In particular, the wafer-separated, riser assembly 782 is shown as being inverted at 783, such that the exposed solder bumps 764 appear along the second exposed wafer surface 704b and a second upper multi-layer device or top riser device 784 layer overhanging a bottom riser device layer 786 to permit close alignment with a proximate IC device, despite any protruding or exposed bonding material along a bonding joint of the IC device to a substrate. An assembly surface contact 774 may be provided, such that the through-assembly via 753 extends from the exposed solder bump 764 to the assembly surface contact 774. The assembly surface contact 774 may be configured for attachment to a wire bond, whereas the solder bump 764 may be configured for attachment for another circuit element, e.g., a circuit element of a substrate. By having the two riser devices, e.g., a lower multi-layer die 712 and an upper multi-layer device 784, or elements, of different sizes, including slightly different sizes, a riser assembly fabrication process sequence may be facilitated, and in at least some applications optimized, to allow for wafer level processing of one or more of a lower multi-layer die 712, an upper multi-layer device 784, and/or a riser assembly 782.

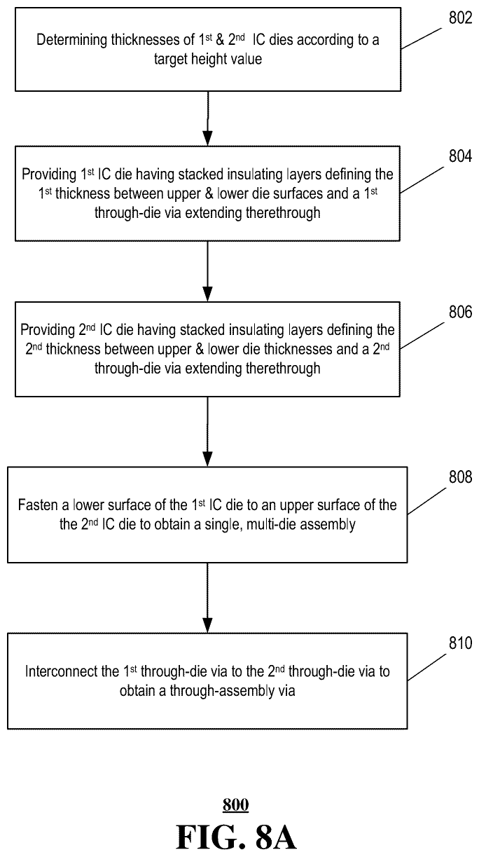

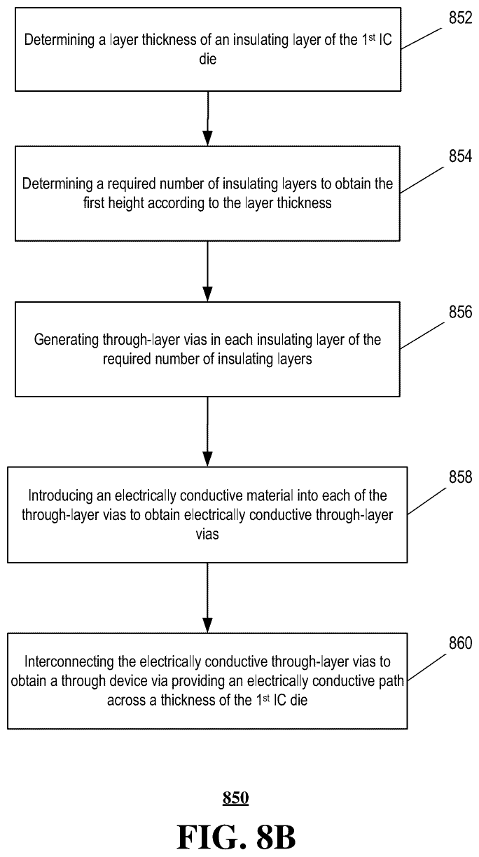

FIG. 8A depicts an illustrative embodiment of a micro-via assembly fabrication process 800 in accordance with various aspects described herein. According to the illustrative embodiment, a first thickness of a first IC die and a second thickness of a second IC die are determined, at 802, according to a target height value. A first IC die is provided, at 804, with a first stacked plurality of layers of insulating material extending between an upper first IC die surface and a lower first IC die surface. The first IC die further comprises a first through-die via extending between the upper first IC die surface and the lower first IC die surface separated by the first IC die thickness. The process 800 also includes providing a second IC die, at 806, that includes a second stacked plurality of layers of insulating material extending between an upper second IC device surface and a lower second IC device surface. The second IC die further includes a second through-die via extending between the upper second IC device surface and the lower second IC device surface, which are separated by the second IC die thickness. The lower first IC die surface is fastened to the upper second IC die surface, at 808, to obtain a multi-die assembly, and the first through-die via is interconnected, at 810, to the second through-die via to obtain a through-assembly via. The through-assembly via is configured to provide a conductive path extending between the upper first IC die surface and the lower second IC die surface.

FIG. 8B depicts an illustrative embodiment of micro-via device fabrication process 850 in accordance with various aspects described herein. According to the example process 850, a providing of a first, passive IC die, e.g., as in 804 (FIG. 8A), further includes determining at 852 a layer thickness of an insulating layer of the first IC die. In at least some embodiments, the layer thickness may be determined according to one or more of a type of material and/or an applicable layering process. For example, the layer thickness may be determined as a maximum attainable layer thickness according to one or more of the type of material or application layering process. Alternatively, or in addition, the layer thickness may be determined as a maximum practical layer thickness, e.g., according to one or more of cost, complexity, resource availability, other environmental considerations, and so on.

According to the example process 850, a required number of insulating layers of the first, passive IC die is determined, at 854, according to the layer thickness. For example, a first IC die thickness, as may have been determined at 802 (FIG. 8A), may be divided by a layer thickness to determine a required number of stacked layers to achieve the IC die thickness.

Further according to the example process 850, a through-layer aperture is generated, at 856, within each of stacked layers of insulating material. The through-layer aperture may be determined by any combination of a mechanical process, e.g., mechanical drilling, a chemical process, e.g., chemical etching, and/or laser process, e.g., laser ablation or drilling. An electrically conducting material may be introduced, at 858, into each aperture of the of the required number through-layer apertures to obtain a required number of through-layer vias. The plurality of through-layer vias may be interconnected, at 860, to obtain a through-die via extending between the upper first IC die surface and the lower first IC die surface. According to the example process 850, the through-die via configured to provide a first conductive path extending between the upper first IC die surface and the lower first IC die surface.

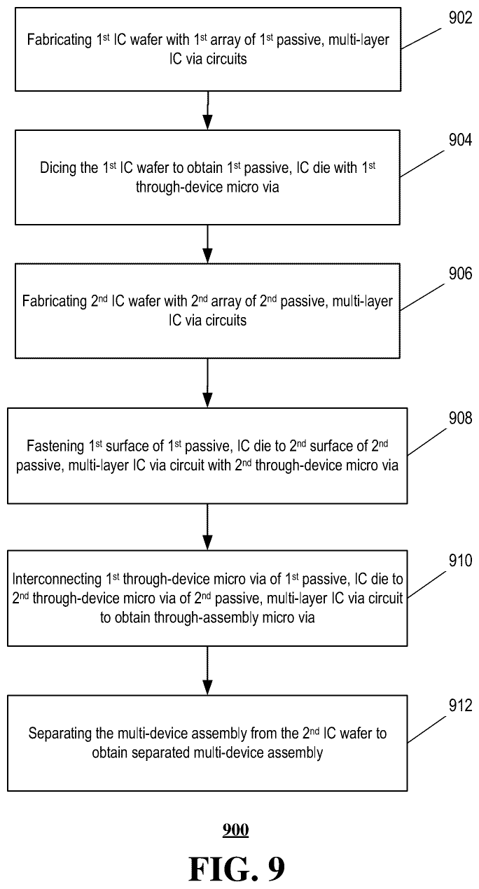

FIG. 9 depicts an illustrative embodiment of a micro-via assembly process 900 in accordance with various aspects described herein. The example process 900 includes fabricating a first IC wafer, at 902, including a first array of first, passive IC circuits. In at least some embodiments, a first, passive IC circuit of the first array of first, passive IC circuits includes a first stacked grouping of layers of insulating material and a first through-device micro via extending across a first thickness of the first, passive IC circuit. According to the example process, the first, passive IC circuit may be separated, at 904, from the first IC wafer to obtain a first, passive IC die. A second IC wafer may be fabricated at 906. The second IC wafer may include a second array of second, passive IC circuits. In at least some embodiments, a second, passive IC circuit of the second array of second, passive IC circuits may include a second stacked grouping of layers of insulating material and a second through-device micro via extending across a second thickness of the second, passive IC circuit.

According to the example process 900, a first surface of the first, passive IC die may be fastened, at 908, to a second surface of the second, passive IC circuit to obtain a multi-device assembly. It is envisioned that the fastening may be performed to ensure an electrical alignment between the first through-device micro via and the second through-device micro via. The first through-device micro via may be interconnected, at 910, to the second through-device micro via to obtain a through-assembly micro via configured to provide a conductive path extending across the multi-device assembly, and the multi-device assembly may be separated, at 912, from the second IC wafer to obtain a separated multi-device assembly.

While for purposes of simplicity of explanation, the respective processes are shown and described as a series of blocks in FIGS. 8A, 8B and 9, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

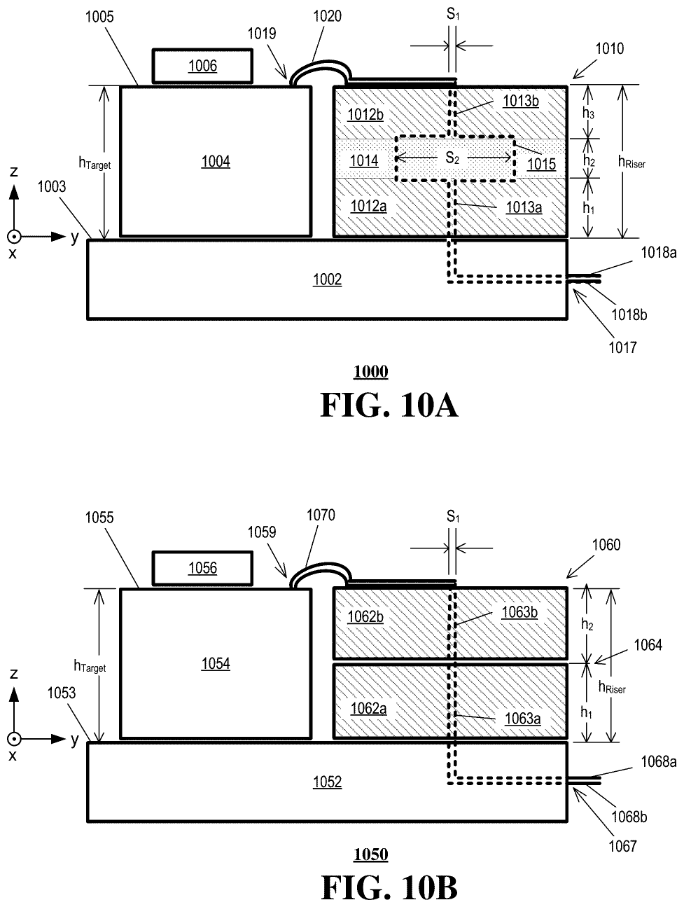

FIG. 10A is a block diagram illustrating a side elevation view of a vertically stacked circuit assembly 1000 including an example, non-limiting embodiment of a single riser device 1010 in accordance with various aspects described herein. The example vertically stacked circuit assembly 1000 includes a base portion, e.g., a supporting structure, which may include a base circuit device 1002, and one or more upper portions, which may include one or more upper circuit devices 1006, displaced with respect to a surface of the base circuit device 1002. For example, the upper device(s) 1006 may be disposed along a vertical direction, e.g., along a z-direction, above an upper surface 1003 of the base circuit device 1002. It is understood that the upper circuit device(s) 1006 may be arranged in a stack and/or layered fashion. At least some of the upper circuit device(s) 1006 may overlap at least a portion of the base circuit device 1002. The illustrative example includes an intermediate portion, e.g., an intermediate circuit device 1004, vertically stacked along the z-direction between the base circuit device 1002 and the upper circuit device(s) 1006. In at least some embodiments, a height of the upper circuit device(s) 1006, h_{Target}, above the upper surface 1003 of the base circuit device 1002 may be substantially greater than thicknesses of traditional semiconductor devices and/or laminated circuit structures suitable for supporting micro vias.

Further, according to the illustrative example, the vertically stacked circuit assembly 1000 includes a first channel 1018a and a second channel 1018b, each channel 1018a, 1018b, generally 1018, adapted for routing electronic signals between different regions of the vertically stacked circuit assembly 1000, e.g., between a first region 1017 of the base circuit device 1002, and a second region 1019 along an upper surface 1005 of the intermediate circuit device 1004, e.g., proximate to the upper circuit device 1006.

One or more of the base circuit device 1002, the intermediate circuit device 1004 or the upper circuit device 1006 may include passive circuitry, active circuitry, or any combination thereof. For example, the base circuit device 1002 may include an electronic circuit provided on and/or in a supporting member, which may be rigid, such as a printed circuit board, a substrate and/or wafer device, a chip, and/or flexible, such as a flexible circuit device, e.g., polyimide flexible PCB, and/or wearable device that includes electrically conductive paths. The conductive paths may be adapted for routing signals alone or in combination with other electrical devices, which may include any combination of active and passive devices. Likewise, the upper and intermediate circuit devices 1006 and 1004 may include any combination of passive circuitry and active circuitry that may be provided on and/or in a supporting member, which may be rigid, such as a printed circuit board, substrate and/or wafer device, or flexible, such as a flex-print device, a wearable device, and the like.

It is understood that the electrically conductive paths may include one or more conductors in the form of lines, wires, cables, etches, and/or signal paths, including transmission lines and/or waveguide, which may include solid and/or hollow waveguide structures adapted for routing electronic signals individually, or in combination with other lines, wires, cables, etches, etc. In at least some embodiments, the signal paths may be single-ended, e.g., referenced to a common circuit point, e.g., an electrical ground and/or shield. Alternatively, or in addition, the signal paths may be differential. In at least some embodiments, the electrically conductive paths may be adapted for routing high-frequency signals, e.g., including frequencies extending into the RF region, e.g., in a range of MHz, and/or GHz and/or THz.

According to the illustrative example, the single riser device 1010 is a passive device including conductive elements, e.g., micro vias, configured to facilitate at least a vertical portion of an electrical interconnection between the first and second regions 1017, 1019 of the vertically stacked circuit assembly 1000. The single riser device 1010 includes a lower structure 1012a and an upper structure 1012b positioned on opposite sides of an intermediate structure 1014. According to the illustrative example, the lower and upper structures 1012a, 1012b, generally 1012, may include respective upper and lower sets of via structures 1013a, 1013b, generally 1013, configured according to first sets of material properties and/or first sets of design constraints or design rules of their respective structures 1012. Likewise, the intermediate structure 1014 may include an intermediate set of via structures 1015, configured according to a second set of material properties and/or a second set of design constraints or design rules. Material properties may include, without limitation, one or more of an electric permittivity, a loss tangent, a magnetic permeability, a conductivity, and so on. Design rules may include, without limitation, a geometric constraint imposed on circuit board, semiconductor device, and/or integrated circuit, such as constraints on a width and/or thickness of a conductive trace or etch, spacing between adjacent conductors, metal fill density, poly density, input/output rules, etc.

According to the illustrative example, the lower and upper structures 1012 may be substantially similar, such that the first sets of material properties and the first sets of design rules or design constraints are substantially similar. Consequently, the upper and lower sets of respective via structures 1013 may be substantially similar. However, according to the illustrative example, the intermediate structure 1014 differs from the lower and upper structures 1012, such that at least one of the second set of material properties or the second set of design rules or design constraints, differs from the first sets of material properties or the first sets of design rules or design constraints. These differences may contribute to differences in design and/or layout between the upper and lower sets of via structures 1013 and the intermediate set of via structures 1015. Generally, differences may include one or more of a via diameter, a via pitch to adjacent vias, a via opening or spacing to other structures, such as anti-pads and/or ground planes.

In high-frequency applications, e.g., in which the micro vias carry RF signals, at least some of the upper, lower and/or intermediate sets of via structures 1013, 1015 may be configured according to an RF performance requirement. By way of example, RF performance requirements may include one or more of an impedance, e.g., a characteristic impedance, an impedance matching, an insertion loss, a return loss, and so on. The first and second channels 1018 of the illustrative example may be dimensioned such that they may be characterized as transmission lines, e.g., being relatively long compared to a highest rise time or signal frequency. Accordingly, each channel may operate according to a respective characteristic impedance, Z₀, which may be the same or different.

According to the illustrative example, the first and second channels 1018 are differential channels as may be configured according to parallel conductive traces or etches. A first characteristic impedance of the first and second channels traversing the lower and upper structures 1012, i.e., Z₀₁, may be determined according to well understood design principles, e.g., according to the trace or etch widths, separation and a material properties, e.g., εᵣ₁, of the surrounding material of the lower and upper structures 1012. Likewise, the material properties and/or design rules or design constraints of the lower and upper structures 1012 may impose a first channel pitch resulting in a first minimum separation or spacing, i.e., S₁, between the first and second channels 1018.

Similarly, a second characteristic impedance of the first and second channels 1018 traversing the intermediate structure 1014, i.e., Z₀₂, may be determined according to the trace or etch widths, separation and material properties, e.g., εᵣ₂, of the surrounding material of the intermediate structure 1014. Likewise, the material properties and/or design rules or design constraints of the intermediate structure 1014 may impose a second channel pitch resulting in a second minimum separation or spacing, i.e., S₂, between the first and second channels 1018 traversing the intermediate structure 1014. To the extent the channel spacings differ, i.e., S₁≠S₂, the upper and/or lower sets of via structures 1013 may be axially displaced from the intermediate via structures 1015. It is understood that a higher impedance may be obtained according to one or more of thinner traces, thicker dielectrics, less copper, lower dielectric constants, or more space between differential pairs. Alternatively, lower impedances may be obtained according to one or more of thicker traces, less dielectrics, more copper, higher dielectric constants or less space between differential pairs.

In order to maintain continuity, the overall micro via structures of the single riser device 1010 may not be collinear, requiring some horizontal circuits, e.g., interconnects, traces, etches, wires and/or cables in order to maintain electrical continuity. The example vertically stacked circuit assembly 1000 illustrates a situation in which the characteristic impedances of the lower and upper structures 1012 are approximately equal to the characteristic impedance of the intermediate structure 1014, i.e., Z₀₁≈Z₀₂, so as to provide favorable RF performance characteristics. It may be advantageous to substantially match the characteristic impedances in this manner, e.g., yielding relatively low values of return loss and/or insertion loss. Unfortunately, matching the characteristic impedances across the substantially different materials may necessitate the different channel spacings, and possibly different spacing and/or trace dimensions of the individual differential trances of each channel 1018a, 1018b. It is appreciated that increased channel spacing may introduce other complications, e.g., requiring additional surface area, cost, complexity.

According to the example vertically stacked circuit assembly, the single riser device 1010 is configured to provide an impedance-controlled, substantially vertical path to raise the channels 1018 to a relatively substantial height, h_{Riser}, above the upper surface 1003 of the base circuit device 1002. The riser height may be selected as a design parameter based on a target height, h_{Target}, of the upper surface 1005 of the intermediate circuit device 1004. Presuming an electrical interconnection is made along the upper surface 1005, e.g., to the upper circuit device 1006 and/or an electrical circuit interconnected to the upper circuit device 1006, a riser height may approximate the target height, e.g., to within some target height offset threshold value, Δh, e.g., h_{Riser}=h_{Target}±Δh. In at least some embodiments threshold value, Δh, may be selected according to a bonding interconnect wire 1020. For example, the bonding interconnect wire 1020 may introduce an RF performance impact, e.g., by way of an inductance value, such that the target height offset threshold value is established according to a maximum tolerable inductance.

In at least some embodiments, the lower structure 1012a comprises a layered structure including multiple layers, whereas the intermediate structure 1014 comprises a relatively thick supporting structure upon which the layered lower structure 1012a may be formed, e.g., according to an HDBU process. By way of example, the supporting structure may include a substantially rigid supporting structure, including glass, ceramic, resin, composite structure, an organic compound, e.g., a polymer structure and the like. For example, the intermediate structure may include a substantially rigid structure, such as a PCB and/or wafer device, e.g., wafer substrate, or an assembly of multiple devices, e.g., flip-chip. Alternatively, or in addition, the intermediate structure may include a flexible member, such as a polyamide flexible circuit. The intermediate set of via structures 1015 may include mechanically drilled, plated through holes. Alternatively, or in addition, the intermediate set of via structures 1015 may include extremely thin holes formed by any suitable process, such as laser drilling and/or semiconductor fabrication processes amenable for micro vias. The holes may be plated through and/or filled with a conductive material, e.g., a metal, such as copper, silver, gold, aluminum, an alloy, e.g., solder, to provide electrical continuity across each layer. In at least some embodiments, the via holes of sequential layers may be substantially aligned, such that the electrically conductive vias may be interconnected during the lamination and fabrication process, thereby forming the intermediate set of via structures 1015 that spans an entire height, h₃, of the lower structure 1012a.

In at least some embodiments, the upper structure 1012b also comprises a layered structure including multiple layers that may be substantially similar to those provided for the lower structure 1012a. Alternatively, or in addition, the upper structure 1012b may include a layered structure differing in one or more of the numbers of layers, the thicknesses of layers, the material properties of the layers than those provided for the lower structure 1012a. It is understood that the single riser device 1010 includes electrical interconnects to ensure electrical continuity along vias of the intermediate set of via structures 1015, spanning the single riser device height, h_{Riser}.

Any suitable laminating process may be utilized to establish the lower and upper structures 1012. In at least some embodiments, the process may include HDBU process. It is understood that fabrication processes that include repeated steps of forming additional layers, drilling via holes, plating and interconnecting may be detrimental to earlier formed layers, e.g., based on thermal stresses, mechanical stresses, chemical stresses, and the like according to the particular fabrication processes. Accordingly, increasing a number of layers would be expected to reduce yields with each additional layer, thus adding to cost and complexity and effectively limiting a maximum number of layers in a single layered structure. Beneficially, the techniques disclosed herein disclose forming assemblies of stacked layered structures to facilitate overall riser device heights substantially greater than practical for a single layered device. Namely, each layered component of a stacked, layered assembly may include a modest number of layers as may be attainable economically, while the overall stacked layered assembly may include a relatively larger number of layers than would be practical and/or even possible for a single riser device 1010. In at least some embodiments, the stacked, layered assemblies may be fabricated having substantially similar material properties and/or design rules and/or design constraints, thereby avoiding the discontinuities introduced by the intermediate structure 1014 as discussed further hereinbelow.

Designing vertical transitions presents various challenges, such as maintaining a constant characteristic impedance in vertical portions, e.g., within the riser devices. For a single layer step, one can easily compensate for this issue, but it becomes more challenging the longer the transition becomes. Often, a vertical transition is too capacitive, e.g., due to design rules and/or material properties limitations. These situations may require a larger space between signals and grounds, which is particularly true for routing differential channels.

Additional challenges may include a pre-determined channel pitch as may be determined from one or more of an interconnecting input and/or an output part, as well as an allowed area the riser can occupy, e.g., within a mechanical context. Therefore, sometimes the vertical transition may be designed at a difference, i.e., at the wrong impedance. These challenges are especially true when going through a “core” layer such as may be encountered in PCB, SLP, HDBU and such materials, as the design rules are generally worse.

FIG. 10B is a block diagram illustrating a side elevation view of a vertically stacked circuit assembly 1050 incorporating another example, non-limiting embodiment of a passive, stacked riser assembly 1060 in accordance with various aspects described herein. The example vertically stacked circuit assembly 1050 includes a base portion, e.g., a supporting structure, which may include a base circuit device 1052, and one or more upper portions, which may include one or more upper circuit devices 1056, displaced with respect to a surface of the base circuit device 1052. For example, the upper device(s) 1056 may be disposed along a vertical direction, e.g., along a z-direction, above a surface 1053 of the base circuit device 1052. It is understood that the upper circuit device(s) 1056 may be arranged in a stack and/or layered fashion, e.g., as described in the previous example, including an intermediate circuit device 1054, vertically stacked along the z-direction between the upper surface 1053 of the base circuit device 1052 and the upper circuit device(s) 1056. The vertically stacked circuit assembly 1050 also includes first and second channels 1068a, 1068b, generally 1068, adapted for routing electronic signals between different regions of the vertically stacked circuit assembly 1050, e.g., between a first region 1067 of the base circuit device 1052, and a second region 1069, e.g., along an upper surface 1055 of the intermediate circuit device 1054.

The illustrative example differs substantially from the preceding example at least in that it includes a stacked riser assembly 1060. The stacked riser assembly 1060 may include a passive device with conductive elements configured to facilitate at least a vertical portion of an electrical interconnection, e.g., micro vias, between the first and second regions 1067, 1069. The stacked riser assembly 1060 includes a lower structure 1062a and one or more upper structure 1062b that may be joined along abutting surfaces of adjacent structures of the stacked riser assembly 1060. For example, the lower and upper structures 1052a, 1052b may be joined along an abutting surface 1054 therebetween using any combination of one or more suitable fastening techniques, such as one or more of a mechanical fastening, a chemical bonding, e.g., using a glue and/or an epoxy, a solder and/or a weld. According to the illustrative example, the lower and upper structures 1062a, 1062b, generally 1062, may include respective upper and lower sets of via structures 1063a, 1063b, generally 1063, configured according to first sets of material properties and/or first sets of design constraints or design rules of their respective structures 1062.

According to the illustrative example, the lower and upper structures 1062 may be substantially similar, at least with respect to material properties and design rules or design constraints. Consequently, the upper and lower sets of respective via structures 1063, e.g., micro vias, may be substantially similar, thereby promoting similarities of one or more of a via diameter, a via pitch to adjacent vias, a via opening or spacing to other structures, such as anti-pads and/or ground planes.

According to the illustrative example, the first and second channels 1068 are differential channels as may be configured according to parallel conductive traces or etches. A first characteristic impedance of the first and second channels 1068 traversing the lower and upper structures 1062, i.e., Z₀₁, may be determined according to well understood design principles, e.g., according to the trace or etch widths, conductor thickness, separation, dielectric thickness and a material properties, e.g., εᵣ₁, of the surrounding material of the lower and upper structures 1062. Likewise, the material properties and/or design rules or design constraints of the lower and upper structures 1062 may impose a first channel pitch resulting in a first minimum separation or spacing, i.e., S₁, between the first and second channels 1068, without encountering the different spacing resulting from the different intermediate structure 1014 (FIG. 10A) of the previous example.

According to the example vertically stacked circuit assembly 1050, the stacked riser assembly 1060 is configured to provide an impedance-controlled, substantially vertical path to raise the channels 1068 to a relatively substantial height, h_{Riser}, above a base surface 1053 of the base circuit device 1052. The riser height may be selected as a design parameter based on a target height, h_{Target}, of the upper surface 1055 of the intermediate circuit device 1054. Presuming an electrical interconnection is made along the upper surface 1055, e.g., to the upper circuit device 1056 and/or an electrical circuit interconnected to the upper circuit device 1056, a riser height that approximates the target height, e.g., to within some target height offset threshold value, Δh, e.g., h_{Riser}=h_{Target}±Δh. Once again, the threshold value may be selected according to a bonding interconnect wire 1070 to maintain an inductance of the bonding interconnect wire 1070 to a tolerable level.

In at least some embodiments, the lower structure 1062a comprises a layered structure including multiple layers. In at least some embodiments, the micro via holes of sequential layers may be substantially aligned, such that the electrically conductive via structure 1063a may be interconnected to span a height, h₁, of the lower structure 1062a. Likewise, the upper structure 1062b comprises a layered structure including multiple layers. In at least some embodiments, the micro via holes of sequential layers may be substantially aligned, such that the electrically conductive via structure 1063b may be interconnected to span a height, h₂, of the upper structure 1062b. In at least some embodiments, the upper and lower via structures 1063a, 1063b may be interconnected, to obtain interconnected via structures 1063a, 1063b that span an entire height, h_{Riser}, of the stacked riser assembly 1060. Interconnections may be established according to any suitable technique, such as using solder balls aligned with the micro vias, conductive paste, mechanical contact, connector, and so on.

In at least some embodiments, material properties and/or design rules or design constraints of the lower and upper structures 1062 may be similar or even identical. Accordingly, configurations of the upper and lower via structures 1063a, 1063b may be similar and/or substantially the same, e.g., having a channel pitch of S₁, while also providing similar and/or substantially the same characteristic impedances, i.e., Z₀₁≈Z₀₂. It is understood that in at least some embodiments, the lower and upper structures 1062 may have the same number and/or configuration of layers, e.g., being similar in number and/or thickness and/or dielectric constant. Alternatively, or in addition, the lower and upper structures 1062 may differ in one or more of number or configuration of layers, while also maintaining common spacings and impedances of the channels 1068. Although the illustrative example stacked riser assembly 1060 includes two lower and upper structures 1062, it is envisioned that other numbers of structures may be included, e.g., three stacked structures, four stacked structures, and so on, in which the stacked structures may be similar and/or different according to number and/or configuration. In at least some embodiments, the heights of the lower and upper structures 1062 may differ, e.g., according to a predetermined height range, such that the overall riser height may be used as a design parameter, being met by a selection of the appropriate height and number of constituent lower, upper and/or intermediate layered structures.

It is further understood that in at least some embodiments, it may be advantageous to provide a riser devices 1010, 1060, in which at least some of the different layered structures and/or intermediate portions provide different characteristic impedances as may be advantageous in transitioning from one impedance, e.g., an impedance of the base circuit devices 1002, 1052, to another impedance, e.g., an impedance of the upper circuit device 1006, 1056. Alternatively, or in addition, one or more of the material properties, design rules and/or design constraints may be varied across component structures of the riser devices 1010, 1060, such that channel pitch and/or physical configuration may be adjusted from one channel pitch to another, as may be advantageous in matching a first channel pitch of the base circuit devices 1002, 1052 and a second channel pitch of the upper circuit device 1006, 1056.

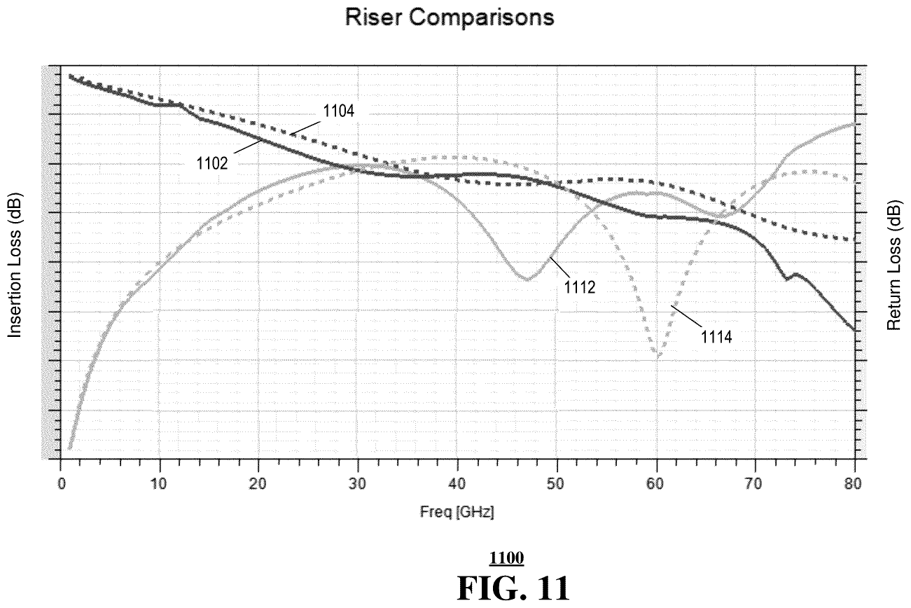

FIG. 11 is a graph 1100 illustrating RF performance representative of the example, non-limiting embodiments of the passive IC riser assemblies illustrated in FIGS. 10A and 10B in accordance with various aspects described herein. A first trace 1102 illustrates a first insertion loss of the single riser device 1010 (FIG. 10A), while a second trace 1104 illustrates a second insertion loss of the stacked riser device 1060 (FIG. 10B). According to the illustrative embodiments, the signal or characteristic impedances of the channels were maintained across the riser devices 1010, 1060, whereas the geometries were allowed to vary as may be necessary, e.g., resulting in the different channel pitches S₁ and S₂ of the single riser device 1010. It is apparent from the graph 1100 that the insertion losses of the first and second traces 1102, 1104 are substantially similar, with a generally similar trend in slope.

A third trace 1112 illustrates a first return loss of the single riser device 1010 (FIG. 10A), while a fourth trace 1114 illustrates a second return loss of the stacked riser assembly 1060 (FIG. 10B). The third and fourth traces 1112, 1114 are substantially similar between about 0-35 GHz and between about 75-80 GHz, with some variation between about 35-70 GHz. It is understood that the variations in return loss may result, at least in part, from differences in physical construction of the sets of vias. It may be concluded that the stacked riser assembly 1060 offers at least some advantages over the signal riser device 1010, at least in that it avoids different channel pitches and/or a requirement for horizontal circuit portions resulting from differences in channel pitches.

The illustrative example single riser device 1010 (FIG. 10A), e.g., an HDBU riser, includes an intermediate or core layer through which the micro vias must extend. The core layer provides different, e.g., rougher, design rules, which in this instance requires an increase in a spacing between signals and/or anti-pads of the vias. The transitions between lower and upper structures 1012 and the intermediate structure 1014 yields a “back-and-forth” design, in which extra line width and/or extra “compensation” were used, leading to a design much more prone to fabrication errors and manufacturing variability. It is also worth noting that the extra lines and/or discontinuities may increase an effective loss of the riser and/or otherwise negatively impact signal integrity of the channels 1018 (FIG. 10A).

In contrast, the illustrative example stacked riser device 1056 (FIG. 10B) substantially uniform design rules across the different structures 1062, without the need for a substantially different intermediate structure 1014 (FIG. 10A) allowed for the use simple fully vertical transitions, without adaptations or any other complications in design and/or fabrication. The latter design of the stacked riser device 1056 is thus more resilient to manufacturing errors, while offering a shorter electrical path that generally leads to better signal integrity performance.

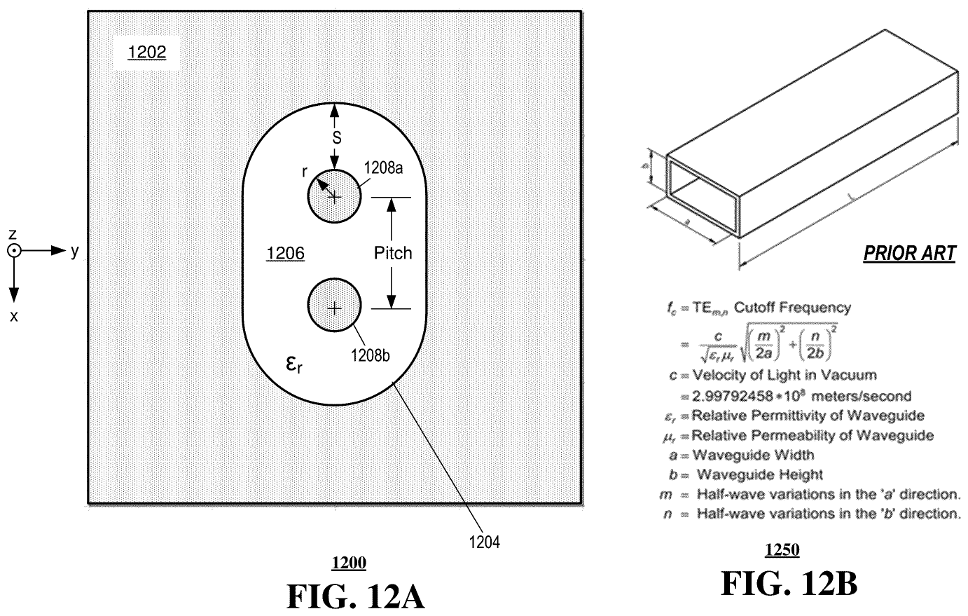

FIG. 12A is a cross-sectional view of an example, non-limiting embodiment of a portion of a passive riser assembly 1200 in accordance with various aspects described herein. The passive riser assembly 1200 includes multiple overlapping layers, with each layer providing electrically conductive vias of a differential channel. The example channel includes a first micro via 1208a and a second via 1208b, vertically aligned, e.g., extending along a z-direction, and offset from each other according to a pitch value, e.g., measured along an x-direction. Each of the first and second micro vias 1208a, 1208b, generally 1208, has a respective radius r, forming a portion of a differential signal path, e.g., a transmission line. The micro vias 1208 are supported in an insulating material, e.g., a dielectric material 1206 having a dielectric constant or an electrical permittivity εᵣ. A signal impedance, e.g., a characteristic impedance of a transmission line formed by the micro vias 1208 may be determined according to one or more of the via radii, the via pitch, and/or the electrical permittivity to obtain a characteristic impedance Z₀ of the transmission line. In at least some embodiments, at least some layers of the passive riser assembly include an electrically conductive structure positioned relative to the micro vias 1208. The illustrative example provides an electrically conductive plane, e.g., a ground plane 1202, defining an opening or aperture 1204 sized and positioned to substantially surround the micro vias 1208, while providing a channel or aperture 1204 to allow the vias to extend vertically. It is understood that, in at least some embodiments, the ground plane 1202 may not be included in at least some portions, i.e., layers, of the passive riser assembly 1200. For example, instead of providing the ground plane 1202, other conductive structures may be provided, such as grounding vias positioned relative to and/or substantially surrounding one or more of the micro vias 1208.

It is understood that the example cross section of the passive riser assembly 1200 may represent a planar view of one layer. Successive layers of a layered portion of the passive riser assembly may include similar configuration, such that the micro vias 1208 may extend vertically within at least a portion of the passive riser assembly.

In at least some instances, the vertical transition within the riser devices 1010, 1056 requires larger signal to ground spacing, S, which leads to relatively large voids or apertures 1024 in the ground plane 1202, effectively forming a cavity and/or waveguide. It is understood that such apertures 1204 may permit energy to effectively leak and otherwise not be propagating properly. It is recognized that sound practice in transmission line design chooses a design such that only the fundamental modes can propagate. Such limitations and/or restrictions to higher order waveguide modes prevent unwanted and/or unexpected energy leakage as may result from resonances and or deleterious changes in the transmission performance. For example, it is recognized that any discontinuity in a transmission line presents an opportunity for a traveling wave in one mode, e.g., a fundamental waveguide mode, to start propagating in another mode, representing unwanted cavity and/or waveguide modes. Therefore, when designing complex structures with many geometric discontinuities such as the example stacked riser assemblies 1050 (FIG. 10B), it is important to operate only within the fundamental modes. This applies to both differential and common modes.

FIG. 12B provides a perspective view of a prior art, hollow rectangular waveguide 1250. The rectangular waveguide has cross sectional dimensions of waveguide width, a, and waveguide height, b. In general, the waveguide may include a relative electric permittivity, εᵣ, and a relative magnetic permeability, μᵣ. A value, c, represents a speed of light in a vacuum, while the value, m, represents a number of half-wave variations in the ‘a’ direction, and the value, n, represents a number of half-wave variations in the ‘b’ direction. Given this configuration, a cutoff frequency, f_{c}, of a transverse electric wave may be determined according to the following equation:

$${f}_{c} = \frac{c}{\sqrt{{ε}_{r} {μ}_{r}}} \sqrt{{( \frac{m}{2 a} )}^{2} + {( \frac{n}{2 b} )}^{2}} \qquad ( Eq . 8 )$$

It is understood that the concept of a cutoff frequency for the example structure 1200 illustrated in FIG. 12A represents a waveguide structure that also presents a cutoff frequency as may be determined according to the particular geometry of the structure 1200, which differs from the example rectangular waveguide 1250. It is appreciated that in at least some instances, a closed form solution of the cutoff frequency, similar to that provided in Eq. 8, may be determined as a function of the structure configuration, e.g., according to the overall configuration including spacing S, pitch, radius, r, and/or aperture 1204. Alternatively, or in addition, the cutoff frequency may be determined experimentally and/or according to numerical techniques, e.g., using a suitable model of the structure illustrated in FIG. 12A. However, for the purpose of analysis and simplicity, it is understood that the cutoff frequency for the rectangular waveguide 1250 presented in Eq. 8, may be used as an estimate suitable for comparative purposes. For example, the material properties of the structure illustrated in FIG. 12A may be utilized, while the rectangular dimensions may be approximated by the aperture 1204.

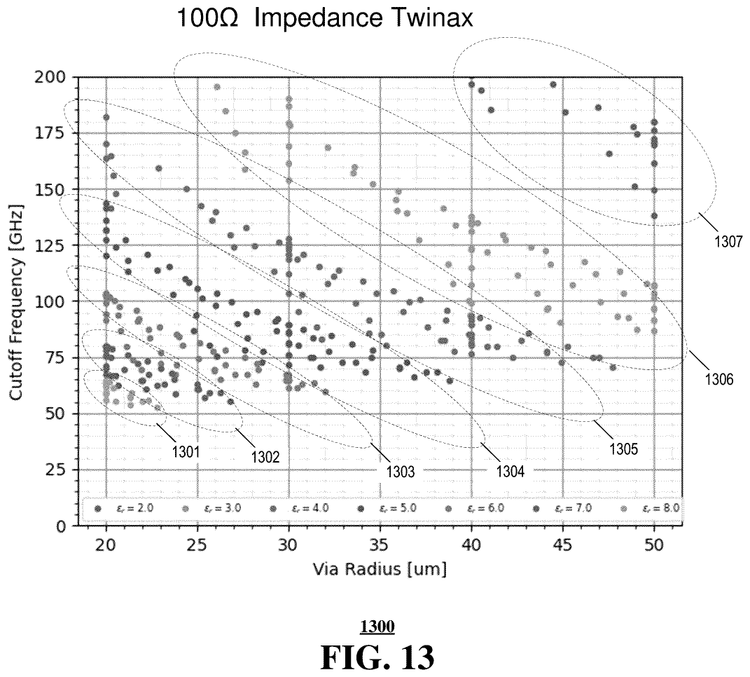

FIG. 13 is a graph 1300 illustrating RF waveguide cutoff frequencies representative of a signal channel of the example, non-limiting embodiments of the passive riser assemblies illustrated in FIGS. 10B and 12A in accordance with various aspects described herein. The plotted points presented in the graph 1300 were obtained using an approximation of the rectangular waveguide cutoff frequency provided by Eq. 8. The calculations were repeated for various electrical permittivities, and for each permittivity, the calculations were repeated for various physical configurations, e.g., via pitch, anti-pad sizes and/or opening widths and heights.

The example graph presents collections of points, with each point representing a cutoff frequency of a 100 Ω twinax in GHz as a function of via radius in micrometers. The calculations were repeated parametrically according to different electrical permittivity values ranging from 2.0 to 8.0 and over a frequency range from about 20 GHz to about 50 GHz. A first design group 1301 represents different configurations of a 100 Ω twinax, with εᵣ=2.0. A second design group 1302 represents different configurations of a 100 Ω twinax, with εᵣ=3.0. A third design group 1303 represents different configurations of a 100 Ω twinax, with εᵣ=4.0. A fourth design group 1304 represents different configurations of a 100 Ω twinax, with εᵣ=5.0. A fifth design group 1305 represents different configurations of a 100 Ω twinax, with εᵣ=6.0. A sixth design group 1306 represents different configurations of a 100 Ω twinax, with εᵣ=7.0. A seventh design group 1307 represents different configurations of a 100 Ω twinax, with εᵣ=8.0. The graph 1300 and/or corresponding calculations may be used to configure the structure illustrated in FIG. 12 to have a cutoff frequency positioned slightly above a maximum channel and/or signal frequency.

In glass, silicon and such risers, an aspect ratio of the micro vias limits how tall can build a riser, thus limiting the applications. Usually, the allowed aspect radios, e.g., a ratio via height to via diameter, are between 7 and 10. By way of example, consider a 100 GHz cutoff frequency transition. In glass, with an εᵣ=6.0, a single device riser would be limited to a thickness of about 140 to 200 μm. However, in stacked, or coreless risers, a lower εᵣ material, e.g., εᵣ=2.8, may be used as there is no need for a rigid intermediate, i.e., glass, section, thus allowing for stacked riser thickness of 350 to 700 μm thick with an ability to stack such coreless risers to an unrestricted number, i.e., N, stacked devices. In contrast, an HDBU core with an εᵣ=4.7, and given ideal design rules, would be limited to 210 μm to 300 μm+350 μm-700 μm*2 for build-up layered sections having εᵣ=3.2, at a height ranging from 910-1700 μm.

According to the various techniques disclosed herein, it is possible to obtain relatively high-aspect-ratio vertical interconnects using stacked arrangements of interconnected low-aspect ratio vias. It is understood that the resulting high-aspect ratio vias may be suitably adapted for high-frequency applications. For example, the vias may be configured with one or more of sizes, shapes, lengths and/or materials suitable for high-frequency applications. Examples include, without limitation, reducing capacitive parasitics through application of low-k polymer material, e.g., liner to the vias. It may be appreciated that the disclosed techniques also facilitate more compact designs and, in many instances, simpler and/or potentially more cost-effective manufacturing processes. It is understood that the disclosed techniques are very versatile and adaptable to many different applications such as interposer, MEMS, and/or millimeter wave applications.

Existing solutions across the industry requiring short wire bonds for high-frequency applications tend to use substrate/PCB mechanical cavities and/or die back grinding techniques to achieve height matching without a need for an RF riser, or to reduce thickness of the RF riser to maintain RF performance. Other industry approaches replace wire bonds with IC flip-chip assemblies. These processes may be limiting in application, costly in fabrication and/or jeopardize performance, e.g., by introducing the possibility of warpage and/or misalignment. Mechanical PCB cavities tend to increase board warpage and consume valuable PCB area resulting in less compact designs.

Extended riser height, such as the examples disclosed herein, may use existing “thin core” and/or “coreless” substrate technologies that utilize laser drilled vias of small diameter to achieve high frequency performance. Utilizing a stacked arrangement of two or more multilayer devices reduces a number of layers, e.g., metal layers, per riser substrate. Beneficially, this reduces substrate complexity, and in many instances, lead times of such devices that might otherwise be encountered during a manufacturing process.

It is further appreciated that the techniques may be applied in a manner that supports a modular approach to RF riser design. An increased number of substrate metal layers as may be required to provide specified riser thickness generally results in added substrate complexity, increased cost, and/or longer lead times. It is also appreciated that a total number of buildup layers is also limited by the substrate factory capability. At least some of these potential issues may be avoided by using a stacked arrangement of more than one multilayer riser device. Thus, a greater overall riser height may be obtained by the stacked arrangement, while the individual riser devices may include fewer layers with a reduced complexity than would otherwise be necessary to achieve a desired thickness.

For example, riser devices having different thicknesses, heights and/or numbers of internal layers may be produced, allowing a mixing and matching of different height riser component devices to achieve RF performance, as well as a predetermined and/or custom height. A relatively small number of standard sizes may be identified, and riser devices mass produced according to these sizes. A custom design application may identify a predetermined or preferred riser assembly height, followed by a determination of a number and types of component riser devices suitable to obtain the preferred height. It is understood that optimization may applied according to one or more parameters, e.g., number of riser devices, maximum height of riser devices, cost, complexity, manufacturing lead times, and so on. Manufacturing process sequence, allowing riser elements to be different sizes, overcomes complications around underfill application and dicing registration accuracy.

The disclosed techniques allow a height of wire bond pads on a riser assembly to become approximately level with an IC device or die to which it may be interconnected via wire bonds. Alternatively, or in addition, a distance between wire bond pads of the riser assembly and an adjacent IC die can be brought consistently close and substantially parallel due to a registering of a top surface of the riser assembly. It is envisioned that such a registration of the top surface of the riser assembly may be performed as part of its wafer level fabrication, e.g., as part of a dicing procedure.

Beneficially, the multi-device riser assemblies disclosed herein provide an alternative to lengthy bond wire, without a need for “thick” core substrates and/or mechanically drilled vias. Maintaining a relatively low dielectric and/or metal layer count per substrate generally improves factory yields, lead times and costs. The multi-device riser assemblies also avoid any need for PCB cavities and/or die back grinding. And, since a wire bond pad portion of the riser assembly may be elevated from a substrate and overhanging a base of the riser assembly, it allows for more efficient use of space on a substrate, such as a PCB housing the IC die and the riser assembly, since any underfill for its base to PCB joint would not require additional clearance for fillets.

The techniques disclosed herein may facilitate a reduced PCB footprint as may be beneficial in at least some applications, such as pluggable modules, e.g., optical pluggable modules. Alternatively, or in addition, the illustrative fabrication process sequences disclosed herein overcome complications around underfill application and dicing registration accuracy. These also allow for higher reliability part as well as consistent dicing distances around wire bond pad area, providing a more repeatable process/product. Processing this assembly as a panel may also reduce manufacturing costs.

It is anticipated that using standard fabrication and assembly techniques, a height tolerance on a stacked riser of about 1 mm, would be typically better than about 10%. A total or final height of the stacked riser may be further fine-tuned by controlling an amount of solder paste at one or more solder ball levels, e.g., solder balls between device layers of an assembly and/or between a finished assembly and a substrate or PCB. It is anticipated that lateral, e.g., x-y registration would benefit from any solder ball self-centering property during an oven reflow. Such precise lateral registration would result in a precise wire bonding pad alignment, e.g., requiring less than a few micrometers of bond wire length mismatch.

It is understood that in at least some embodiments, assemblies of stacked riser devices, once assembled, may be categorized as surface mount technology (SMT) components, or simply single risers.

One or more aspects of the subject disclosure include an integrated circuit (IC) assembly comprising a first IC die. The first IC die includes a first plurality of stacked insulating layers having a first thickness extending between an upper first IC die surface and a lower first IC die surface and a first through-device via configured to provide a first conductive path extending between the upper first IC die surface and the lower first IC die surface. The IC assembly further comprises a second IC die affixed to the first IC die in a stacked arrangement. The second IC die includes a second plurality of stacked insulating layers having a second thickness extending between an upper second IC die surface and a lower second IC die surfaces. The upper second IC die surface is coupled to the lower first IC die surface and a second through-device via configured to provide a second conductive path extending between the upper second IC die surface and the lower second IC die surface, wherein the second through-device via is electrically coupled to the first through-device via to obtain a through-assembly via configured to provide a through-assembly conductive path extending from the upper first IC die surface to the lower second IC die surface.

In at least some embodiments, the first IC die, and the second IC die of the aforementioned IC assembly are passive devices.

In at least some embodiments, the first IC die of the aforementioned IC assembly further comprises a bonding contact at the upper first IC die surface and electrically coupled to the first through-device via.

In at least some embodiments, the first IC die of the aforementioned IC assembly further comprises a bonding contact at the upper first IC die surface and electrically coupled to the first through-device via, wherein the first thickness and the second thickness are substantially equivalent.

In at least some embodiments of the first IC die of the aforementioned IC assembly, a height of the bonding contact with respect to the lower second IC die surface is determined according to the first thickness and the second thickness.

In at least some embodiments of the first IC die of the aforementioned IC assembly, a height of the bonding contact with respect to the lower second IC die surface is determined according to the first thickness and the second thickness, wherein the height of the bonding contact comprises a target assembly height, and wherein at least one of the first thickness and the second thickness is determined according to the target assembly height.

In at least some embodiments, the first plurality of stacked insulating layers of the aforementioned IC assembly further comprises a first plurality of electrically coupled micro vias, with each micro via of the first plurality of electrically coupled micro vias obtained via a laser ablation process.

In at least some embodiments, the first plurality of stacked insulating layers of the aforementioned IC assembly further comprises an organic compound.

In at least some embodiments, the first plurality of stacked insulating layers of the aforementioned IC assembly comprises a low-K dielectric material having a relatively small dielectric constant.

In at least some embodiments, the through-assembly via of the aforementioned IC assembly comprises a passive electrical circuit presenting a circuit impedance that facilitates high-frequency operation.

In at least some embodiments, the aforementioned IC assembly further comprises a lateral offset distance determined according to a difference between a first edge of the lower first IC die surface and a second edge of the upper second IC die surface, the first edge extending beyond the second edge by the lateral offset distance.

In at least some embodiments, the aforementioned IC assembly further comprises a lateral offset distance determined according to a difference between a first edge of the lower first IC die surface and a second edge of the upper second IC die surface, the first edge extending beyond the second edge by the lateral offset distance, wherein the lateral offset distance is determined according to a difference between a first surface area of the first IC die and a second surface area of the second IC die.

One or more aspects of the subject disclosure include a micro-via assembly fabrication method that comprises determining a first integrated circuit (IC) die thickness and a second IC die thickness according to a target height value. The micro-via assembly fabrication method further comprises providing a first, passive IC die, wherein the first, passive IC die comprises a first stacked plurality of layers of insulating material extending between an upper first IC die surface and a lower first IC die surface and wherein the first, passive IC die further comprises a first through-die via extending between the upper first IC die surface and the lower first IC die surface separated by the first IC die thickness. The micro-via assembly fabrication method further comprises providing a second, passive IC die, wherein the second IC die comprises a second stacked plurality of layers of insulating material extending between an upper second IC device surface and a lower second IC device surface and wherein the second, passive IC die further comprises a second through-die via extending between the upper second IC device surface and the lower second IC device surfaces separated by the second IC die thickness. The micro-via assembly fabrication method, further comprises fastening the lower first IC die surface to the upper second IC die surface to obtain a multi-die assembly, and interconnecting the first through-die via to the second through-die via to obtain a through-assembly via, the through-assembly via configured to provide a conductive path extending between the upper first IC die surface and the lower second IC die surface.

In at least some embodiments, the providing of the first, passive IC die of the micro-via assembly fabrication method further comprises determining a layer thickness, determining a required number of layers of the first plurality of stacked layers of insulating material according to the layer thickness, generating a plurality of through-layer apertures within the first plurality of stacked layers of insulating material, introducing an electrically conducting material into each aperture of the plurality of through-layer apertures to obtain a plurality of through-layer vias, and interconnecting the plurality of through-layer vias to obtain a through-die via extending between the upper first IC die surface and the lower first IC die surface The through-die via is configured to provide a first conductive path extending between the upper first IC die surface and the lower first IC die surface, to obtain an extended micro-via assembly fabrication method.

In at least some embodiments, the providing of the first, passive IC die of the extended micro-via assembly fabrication method further comprises generating a first insulating layer of the first plurality of stacked layers of insulating material according to an additive process, applying a laser ablation process to the first insulating layer to obtain a first through-layer aperture of the plurality of through-layer apertures, introducing an electrical conductor into the first through-layer aperture to obtain a first through-layer via and generating upon a surface of the first insulating layer a conductive layer in communication with the first through-layer via. The conductive layer facilitates an electrical coupling between the first through-layer via and a second through-layer via of an adjacent layer of the first plurality of stacked layers of insulating material, to obtain a further extended micro-via assembly fabrication method.

In at least some embodiments, the additive process of the further extended micro-via assembly fabrication method further comprises depositing an organic compound of the first insulating layer of the first plurality of stacked layers of insulating material upon a substrate.

In at least some embodiments, the introducing of the electrical conductor into the first through-layer aperture of the further extended micro-via assembly fabrication method further comprises applying a metal layer to the surface of the first insulating layer of the first plurality of stacked layers of insulating material, wherein the generating of the conductive layer further comprises applying a subtractive process to the metal layer.

One or more aspects of the subject disclosure include a micro-via assembly fabrication method, comprising fabricating a first IC wafer comprising a first array of first, passive IC circuit, a first, passive IC circuit of the first array of first, passive IC circuits comprising a first stacked plurality of layers of insulating material and a first through-device micro via extending across a first thickness of the first, passive IC circuit, and separating the first, passive IC circuit from the first IC wafer to obtain a first, passive IC die. The micro-via assembly fabrication method further comprises fabricating a second IC wafer comprising a second array of second, passive IC circuits, wherein a second, passive IC circuit of the second array of second, passive IC circuits comprises a second stacked plurality of layers of insulating material and a second through-device micro via extending across a second thickness of the second, passive IC circuit. The micro-via assembly fabrication method further comprises fastening a first surface of the first, passive IC die to a second surface of the second, passive IC circuit to obtain a multi-device assembly, wherein the fastening ensures an electrical alignment between the first through-device micro via and the second through-device micro via. The micro-via assembly fabrication method further comprises interconnecting the first through-device micro via to the second through-device micro via to obtain a through-assembly micro via configured to provide a conductive path extending across the multi-device assembly and separating the multi-device assembly from the second IC wafer to obtain a separated multi-device assembly.

In some embodiments, the micro-via assembly fabrication method further comprises inverting the first, passive IC die prior to fastening a first surface of the first, passive IC die to a second surface of the second, passive IC circuit.

In some embodiments, the interconnecting of the first through-device micro via to the second through-device micro via of the micro-via assembly fabrication method further comprises a surface mount solder flow process.

The terms “first,” “second,” “third,” and so forth, as used in the claims, unless otherwise clear by context, is for clarity only and does not otherwise indicate or imply any order in time. For instance, “a first determination,” “a second determination,” and “a third determination,” does not indicate or imply that the first determination is to be made before the second determination, or vice versa, etc.

Further, the various embodiments can be implemented as a method, apparatus or article of manufacture using standard programming and/or engineering techniques to produce software, firmware, hardware, or any combination thereof to control a computer to implement the disclosed subject matter. The term “article of manufacture” as used herein is intended to encompass semiconductor devices, wafers, integrated circuits, circuit modules, modules, systems and/or components incorporating semiconductor devices, as well as a computer program accessible from any computer-readable device or computer-readable storage/communications media. For example, computer readable storage media can include, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to,” “coupled to,” and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. An integrated circuit (IC) assembly, comprising:
a first IC die comprising:
a first plurality of overlapping insulating layers having a first thickness extending between an upper first IC die surface and a lower first IC die surface; and
a first through-device via configured to provide a first conductive path extending between the upper first IC die surface and the lower first IC die surface; and
a second IC die affixed to the first IC die in a stacked arrangement, wherein the second IC die comprises:
a second plurality of stacked insulating layers having a second thickness extending between an upper second IC die surface and a lower second IC die surfaces, wherein the upper second IC die surface is coupled to the lower first IC die surface; and
a second through-device via configured to provide a second conductive path extending between the upper second IC die surface and the lower second IC die surface, wherein the second through-device via is electrically coupled to the first through-device via to obtain a through-assembly via configured to provide a through-assembly conductive path extending from the upper first IC die surface to the lower second IC die surface.

2. The IC assembly of claim 1, wherein the first through-device via presents a first circuit impedance and the second through-device via presents a second circuit impedance.

3. The IC assembly of claim 2, wherein the first circuit impedance and the second circuit impedance are substantially equivalent.

4. The IC assembly of claim 3, wherein a first channel pitch determines a first minimum separation between the first through-device via and a first proximate through-device via, wherein a second channel pitch determines a second minimum separation between the second through-device via and a second proximate through-device via, and wherein the first channel pitch and the second channel pitch are substantially equivalent.

5. The IC assembly of claim 1, wherein the first IC die comprises a waveguide defining a longitudinal cavity comprising at least a portion of the first through-device via, wherein a transverse dimension of the longitudinal cavity determines a cutoff frequency above which energy does not propagate along the first through-device via.

6. The IC assembly of claim 1, wherein the first IC die further comprises a bonding contact at the upper first IC die surface and electrically coupled to the first through-device via.

7. The IC assembly of claim 6, wherein the first thickness and the second thickness are substantially equivalent.

8. The IC assembly of claim 6, wherein a height of the bonding contact with respect to the lower second IC die surface is determined according to the first thickness and the second thickness.

9. The IC assembly of claim 8, wherein the height of the bonding contact comprises a target assembly height, wherein at least one of the first thickness and the second thickness is determined according to the target assembly height.

10. The IC assembly of claim 1, wherein the first plurality of overlapping insulating layers further comprises:
a first plurality of electrically coupled micro vias, each micro via of the first plurality of electrically coupled micro vias obtained via a laser ablation process.

11. The IC assembly of claim 1, further comprising a lateral offset distance determined according to a difference between a first edge of the lower first IC die surface and a second edge of the upper second IC die surface, the first edge extending beyond the second edge by the lateral offset distance.

12. The IC assembly of claim 11, wherein the lateral offset distance is determined according to a difference between a first surface area of the first IC die and a second surface area of the second IC die.

13. A micro-via assembly fabrication method, comprising:
determining a first integrated circuit (IC) die thickness and a second IC die thickness according to a target height value;
providing a first, passive IC die, wherein the first, passive IC die comprises a first stacked plurality of layers of insulating material extending between an upper first IC die surface and a lower first IC die surface and wherein the first, passive IC die further comprises a first through-die via extending between the upper first IC die surface and the lower first IC die surface separated by the first IC die thickness;
providing a second, passive IC die, wherein the second IC die comprises a second stacked plurality of layers of insulating material extending between an upper second IC device surface and a lower second IC device surface and wherein the second, passive IC die further comprises a second through-die via extending between the upper second IC device surface and the lower second IC device surfaces separated by the second IC die thickness;
fastening the lower first IC die surface to the upper second IC die surface to obtain a multi-die assembly; and
interconnecting the first through-die via to the second through-die via to obtain a through-assembly via, the through-assembly via configured to provide a conductive path extending between the upper first IC die surface and the lower second IC die surface.

14. The micro-via assembly fabrication method of claim 13, wherein the providing of the first, passive IC die further comprises:
determining a layer thickness;
determining a required number of layers of the first plurality of stacked layers of insulating material according to the layer thickness;
generating a plurality of through-layer apertures within the first plurality of stacked layers of insulating material;
introducing an electrically conducting material into each aperture of the plurality of through-layer apertures to obtain a plurality of through-layer vias; and
interconnecting the plurality of through-layer vias to obtain a through-die via extending between the upper first IC die surface and the lower first IC die surface, the through-die via configured to provide a first conductive path extending between the upper first IC die surface and the lower first IC die surface.

15. The micro-via assembly fabrication method of claim 14, wherein the providing of the first, passive IC die further comprising:
generating a first insulating layer of the first plurality of stacked layers of insulating material according to an additive process;
applying a laser ablation process to the first insulating layer to obtain a first through-layer aperture of the plurality of through-layer apertures;
introducing an electrical conductor into the first through-layer aperture to obtain a first through-layer via; and
generating upon a surface of the first insulating layer a conductive layer in communication with the first through-layer via, the conductive layer facilitating an electrical coupling between the first through-layer via and a second through-layer via of an adjacent layer of the first plurality of stacked layers of insulating material.

16. The micro-via assembly fabrication method of claim 15, wherein the additive process further comprises deposition of an organic compound of the first insulating layer of the first plurality of stacked layers of insulating material upon a substrate.

17. The micro-via assembly fabrication method of claim 15, wherein the introducing of the electrical conductor into the first through-layer aperture further comprises applying a metal layer to the surface of the first insulating layer of the first plurality of stacked layers of insulating material, and wherein the generating of the conductive layer further comprises applying a subtractive process to the metal layer.

18. A micro-via assembly fabrication method, comprising:
fabricating a first IC wafer comprising a first array of first, passive IC circuit, a first, passive IC circuit of the first array of first, passive IC circuits comprising a first stacked plurality of layers of insulating material and a first through-device micro via extending across a first thickness of the first, passive IC circuit;
separating the first, passive IC circuit from the first IC wafer to obtain a first, passive IC die;
fabricating a second IC wafer comprising a second array of second, passive IC circuit, a second, passive IC circuit of the second array of second, passive IC circuits comprising a second stacked plurality of layers of insulating material and a second through-device micro via extending across a second thickness of the second, passive IC circuit;
fastening a first surface of the first, passive IC die to a second surface of the second, passive IC circuit to obtain a multi-device assembly, wherein the fastening ensures an electrical alignment between the first through-device micro via and the second through-device micro via; and
interconnecting the first through-device micro via to the second through-device micro via to obtain a through-assembly micro via configured to provide a conductive path extending across the multi-device assembly; and
separating the multi-device assembly from the second IC wafer to obtain a separated multi-device assembly.

19. The micro-via assembly fabrication method of claim 18, further comprising:
inverting the first, passive IC die prior to fastening a first surface of the first, passive IC die to a second surface of the second, passive IC circuit.

20. The micro-via assembly fabrication method of claim 18, wherein the interconnecting the first through-device micro via to the second through-device micro via comprises a surface mount solder flow process.
